(19) United States
(12) Patent Application Publication
(10) Pub. No.: US 2020/0144151 A1
(43) Pub. Date: May 7, 2020

(54) OPTICAL TRNSCEIVER HAVING HEAT DISSIPATION

(71) Applicant: SAMTEC, INC., New Albany, IN (US)

(72) Inventors: R. Brad BETTMAN, Mountain View, CA (US); David LANGSAM, Sunnyvale, CA (US); Jignesh SHAH, Santa Clara, CA (US)

(21) Appl. No.: 16/625,029

(22) PCT Filed: Jun. 29, 2018
(86) PCT No.: PCT/US2018/040184

§ 371 Date: Dec. 20, 2019

Related U.S. Application Data
(60) Provisional application No. 62/527,711, filed on Jun. 30, 2017.
(60) Provisional application No. 62/614,626, filed on Jan. 8, 2018.

(51) Int. Cl. H01L 23/367; H01L 23/498; H01L 23/00; H01L 23/13; H01S 5/022; H01L 31/02; H01L 25/16; H01L 31/024; H04B 10/40

(52) U.S. Cl. CPC H01L 23/3675; H01L 23/49811; H01L 24/05; H01L 23/13; H01L 24/48; H01S 5/02248; H01S 5/02469; H01L 31/02019; H01L 25/167; H01L 31/024; H01L 23/3672; H04B 10/40; H01L 31/02005

(57) ABSTRACT

An optical transceiver provides substantial thermal isolation between an IC die and an optical element that is in electrical communication with the IC die. The IC die is further in electrical communication with a substrate that supports the optical element and the IC die. The transceiver includes an IC heat spreader that is configured to dissipate heat generated from the IC die. The IC die and the optical element can be substantially thermally isolated from each other so as to prevent the heat generated from the IC die from causing the optical elements to overheat.

### CROSS-REFERENCE TO RELATED APPLICATIONS

This claims priority to U.S. Provisional Patent Application Ser. No. 62/527,711 filed Jun. 30, 2017 and U.S. Provisional Patent Application Ser. No. 62/614,626 filed Jan. 8, 2018, the disclosure of each of which is hereby incorporated by reference as if set forth in their entireties herein.

### BACKGROUND

Optical transceivers generally include an optical transmitter and an optical receiver. The optical transmitter typically receives electrical signals, and activates a light source to generate optical carrier signals that correspond to the received electrical signals for use in an optical communication system. The light source is typically a laser light source, such as a VCSEL or some other type of laser. The optical transmitter often includes an integrated circuit (IC) die that is configured as a driver that is electrically connected to the VCSEL and drives the pulsation of the VCSEL. Unfortunately, VCSEL performance is degraded by operating at elevated temperatures. Depending on the type of VCSEL used, operating VCSELs at temperatures exceeding 70 C, 80 C, or 85 C may result in unacceptable VCSEL lifetime or electrical-to-optical conversion efficiency. Generally the upper limit of the VCSEL operating temperature is significantly lower than the operating temperature limit of an IC, which may be situated adjacent the VCSEL. For example, the IC may have an operating temperature limit of 100 C. While the IC can withstand a higher operating temperature, it typically generates an order of magnitude more waste heat than the VCSEL. For example, in operation the IC may generate 2.0 W of waste heat while the VCSEL may only generate 0.1 W of waste heat.

The optical receivers generally include one or more photodetectors that receive optical signals from an optical cable, and convert the optical signals to electrical signals that can have current levels proportional with the quantity of optical photons per unit time received in the optical signals. The optical receiver further typically includes a current-to-voltage converter, such as a transimpedance amplifier (TIA) that amplifies the electrical signals to voltage levels that are usable in data communication systems. The TIA is typically constructed as an integrated circuit (IC) die. The IC die that provides the TIA can be the same IC die that provides the VCSEL driver, or the IC dies can be separate IC dies as desired. The photodetectors are often configured as photodiodes that, as with the VCSELs, are adversely affected at high operating temperatures. The light source of the transmitter and photodiode of the receiver may generally be referred to as optical elements, since they all are involved either with the conversion of an electrical signal to an optical signal or vice versa.

While the performance of the optical elements are adversely affected by high operating temperatures, it is typically desirable to situate these components adjacent their respective IC die that generates and/or receives high speed electrical signals. The high speed electrical signals may be digital signals having communication rates greater than 10 Gpbs and in some cases significantly higher rates such as 28 Gpbs, 56 Gpbs, or even higher data rates. To maintain acceptable signal integrity on these high speed signals it is desirable to make the conductive electrical path between the IC and the optical elements as short as possible. A convenient, low cost method of making a conductive electrical path is with wire bonds that electrically connect conductive pads situated on the top of an IC die and with conductive pads on an optical element.

There is thus a need to provide a thermal path to dissipate heat generated by the closely situated optical elements and electrical components during operation. There is also a need to provide thermal isolation between the IC and optical elements so that heat generated by the IC does not raise the temperature of the optical elements above their operating limit.

### SUMMARY

In one aspect of the present disclosure, an optical transceiver includes a substrate that defines an upper surface and a lower surface opposite each other along a transverse direction, and at least one first electrical pad disposed on the upper surface. The transceiver can also include an IC heat spreader, and an IC die in thermal communication with the IC heat spreader, a first group of at least one IC electrical pad disposed on the IC die, and a second group of at least one IC electrical pad disposed on the IC die. The transceiver can also include a thermal conductor, and an optical element in thermal communication with the thermal conductor. The transceiver can also include at least one optical element electrical pad disposed on the optical element. The transceiver can also include at least one first electrical conductor that extends from a respective one of the at least one first electrical pad of the substrate to a respective one of the at least one IC electrical pad of the first group. The transceiver can also include at least one second electrical conductor that extends from a respective one of the at least one IC electrical pad of the second group to a respective one of the at least one optical element electrical pad.

### BRIEF DESCRIPTION OF THE DRAWINGS

FIG. 1A is an exploded perspective view of a portion of an optical transceiver in accordance with one example;

FIG. 1B is a perspective view of the portion of an optical transceiver illustrated in FIG. 1;

FIG. 1C is a perspective view of the portion of an optical transceiver constructed in accordance with another example;

FIG. 2 is a schematic top plan view of a transceiver substrate constructed in accordance with one embodiment;

FIG. 3A is a top plan view of the transceiver substrate illustrated in FIG. 2, but including a pair of notches in accordance with one embodiment;

FIG. 3B is an exploded top plan view of a portion of the transceiver substrate illustrated in FIG. 3A, but including a pair of notches in accordance with an alternative embodiment;

FIG. 4A is a schematic top plan view of an IC heat dissipation assembly including an IC heat spreader and an IC die supported by the IC heat spreader;

FIG. 4B is a sectional side elevation view of the IC heat dissipation assembly illustrated in FIG. 4A, taken along line 4B-4B;

FIG. 4C is a sectional side elevation view of the IC heat dissipation assembly illustrated in FIG. 4A, taken along line 4C-4C;

FIG. 5A is a schematic top plan view of an optical element heat dissipation assembly including an optical element heat spreader and an optical element supported by the optical element heat spreader;

FIG. 5B is a side elevation view of the optical element heat dissipation assembly illustrated in FIG. 5A, taken along line 5B-5B;

FIG. 5C is a side elevation view of the optical element heat dissipation assembly illustrated in FIG. 5A, taken along line 5C-C;

FIG. 6 is a schematic top plan view of a portion of an optical transceiver, including the IC heat dissipation assembly illustrated of FIG. 5A and the optical element heat dissipation assembly of FIG. 6A mounted to the transceiver substrate illustrated in FIG. 3A;

FIG. 7A is a sectional side elevation view of the portion of the optical transceiver illustrated in FIG. 6, taken along line 7A-7A;

FIG. 7B is a sectional side elevation view of the portion of the optical transceiver similar to FIG. 7A, but showing the IC die in a tilted position;

FIG. 7C is a sectional side elevation view of the portion of the optical transceiver similar to FIG. 7A, but including the transceiver substrate illustrated in FIG. 3B;

FIG. 8A is a sectional side elevation view of the portion of the optical transceiver illustrated in FIG. 6, taken along line 8A-8A, illustrating a heat dissipation path of the electrical component;

FIG. 8B is a sectional side elevation view of the portion of the optical transceiver similar to FIG. 8A, but showing the transceiver substrate as including a thermally conductive layer in thermal communication with IC heat spreader;

FIG. 8C is a sectional side elevation view of the portion of the optical transceiver similar to FIG. 8B, but showing the transceiver substrate as including a thermally conductive central layer in thermal communication with both the IC die the and the IC heat spreader, and peripheral thermally conductive layers in thermal communication with the IC head spreader;

FIG. 9A is a sectional side elevation view of a portion of the optical transceiver, illustrating a heat dissipation path of the optical element;

FIG. 9B is a top plan view of the optical transceiver in accordance with an alternative embodiment;

FIG. 10A is a sectional side elevation view of the portion of the optical transceiver illustrated in FIG. 9A, but including a heat sink in one embodiment;

FIG. 10B is a sectional side elevation view of the portion of the optical transceiver similar to FIG. 10A, but showing the heat sink constructed in accordance with an alternative embodiment;

FIG. 11 is a top plan view of a portion of an optical transceiver including a split heat spreader in accordance with an alternative embodiment;

FIG. 12A is an exploded perspective view of a portion of an optical transceiver including a thermal conductor in accordance with still another example including a slot that separates at least one optical element from an IC die, and a heat spreader that is in thermal communication with the thermal conductor so as to establish a path of thermal conduction;

FIG. 12B is a perspective view of the portion of the optical transceiver illustrated in FIG. 12A;

FIG. 12C is a sectional side elevation view of the portion of the optical transceiver illustrated in FIG. 12A, showing the IC heat spreader in contact with the thermal conductor;

FIG. 12D is a sectional side elevation view of the portion of the optical transceiver similar to FIG. 12C, but showing the thermal conductor having first and second regions of different heights so as to increase the height of the optical elements;

FIG. 12E is a sectional side elevation view of the portion of the optical transceiver similar to FIG. 12C, but showing the thermal conductor having first and second regions of different heights in another example so as to decrease the height of the IC die;

FIG. 12F is a sectional side elevation view of the portion of the optical transceiver similar to FIG. 12C, but showing the thermal conductor supporting the IC die in a tilted position;

FIG. 13A is a top, left, front perspective view of the thermal conductor;

FIG. 13B is a bottom, rear, right perspective view of the thermal conductor;

FIG. 13C is a top plan view of the thermal conductor;

FIG. 13D is a bottom plan view of the thermal conductor;

FIG. 13E is a front elevation view of the thermal conductor;

FIG. 13F is a rear elevation view of the thermal conductor;

FIG. 13G is a right side elevation view of the thermal conductor; and

FIG. 13H is a left side elevation view of the thermal conductor.

### DETAILED DESCRIPTION

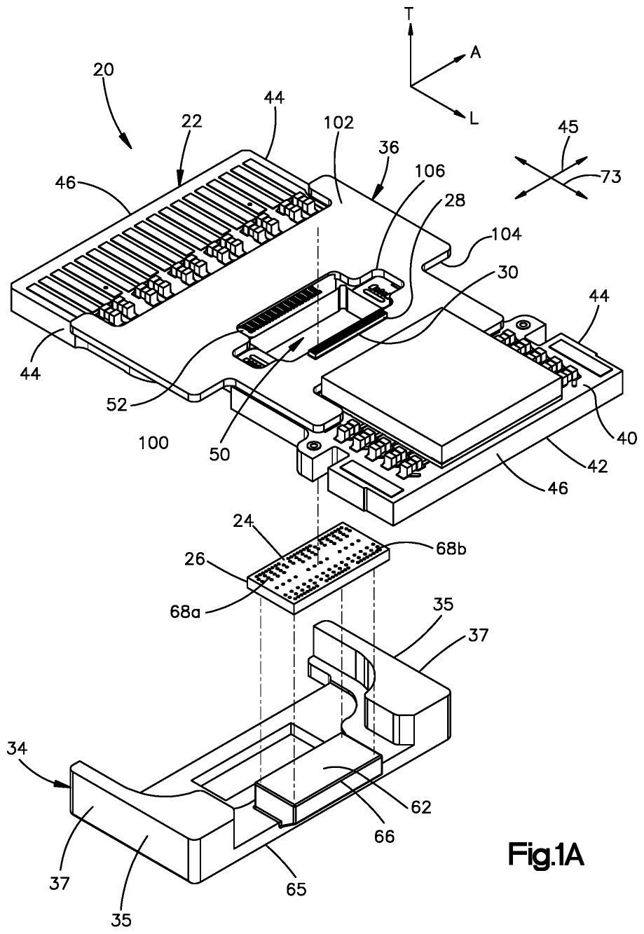

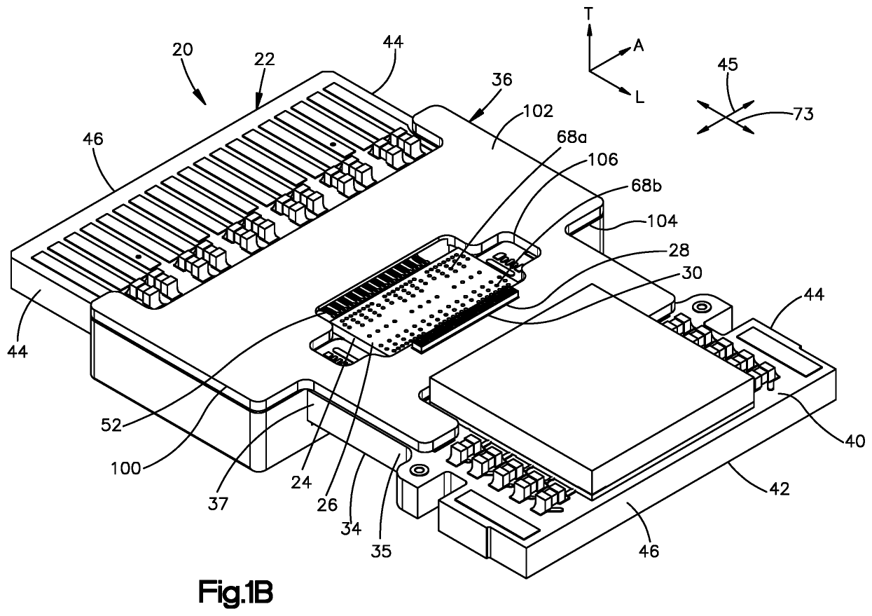

Referring initially to FIGS. 1A-1C, an optical transceiver 20 includes a transceiver substrate 22, and at least one optical element 28 supported by the substrate 22. The term “at least one” as used herein refers to examples that include one, and examples that include a plurality. Further, reference to “an” or “the” with reference to an element described herein can also include a plurality of the elements unless otherwise indicated. Similarly, reference to a “plurality” with reference to an element described herein can also include a single element. Thus, the terms “a” or “an” or “the,” the term “at least one,” and the term “a plurality” can be used interchangeably herein unless otherwise indicated.

In one example, the optical transceiver 20 can include an optical transmitter. The optical transmitter can be configured to receive electrical signals, and activate a light source to generate optical carrier signals that correspond to the received electrical signals for use in an optical communication system. Thus, the optical transceiver can include an electrical component 24. The electrical component 24 can be configured as an electrical transmitter component. For instance, the electrical transmitter component can be configured as an integrated circuit (IC). The integrated circuit can be constructed as an IC die 26. Thus, reference to the integrated circuit can apply to the IC die 26, and vice versa. The optical element 28 of the transmitter, and thus of the optical transceiver 20, can be configured as at least one light source 30 that generates and emits optical carrier signals corresponding to the received electrical signals. The light source is typically a laser light source, such as a VCSEL or an alternative type of laser. The IC die 26 can be in electrical communication with both the transceiver substrate 22 and the light source 30. Thus, the IC die 26 can be configured as a light source driver that drives the pulsation of the light source 30. Thus, the IC die 26 is in electrical communication with the optical element 28. The performance of the light source can adversely affected at high operating temperatures. It should be appreciated that the at least one optical element can include a plurality of optical elements as desired. A plurality of light sources 30 is typically included.

While various elements of the optical transceiver 20 have been described with respect to an optical transmitter, it should be appreciated that the optical transceiver 20 can alternatively or additionally include an optical receiver. The optical receiver is configured to receive optical signals, and convert the received optical signals to electrical signals suitable for transmission in a data communication system. Thus, the optical element 28 can be configured as an array of photodetectors that receive optical signals from an optical cable, and convert the optical signals to electrical signals that can have current levels proportional with the quantity of optical photons per unit time received in the optical signals. The photodetectors can be configured as photodiodes whose performance can be adversely affected at high operating temperatures. The electrical component 24 can be configured as a current-to-voltage converter, such as a transimpedance amplifier (TIA) that receives the electrical signals from the photodetectors amplifies the electrical signals to voltage levels that are usable in data communication systems. The TIA can be constructed as an IC die, such that the IC die 26 can be configured as a TIA. The IC die 26 that provides the TIA can be the same IC die 26 that provides the light source driver. Alternatively, separate IC dies can define the TIA and the light source driver, respectively. It should be appreciated that the optical elements 28 can include one or both of at least one light source 30 and at least one photodetector as desired.

As will be appreciated from the description below, the optical transceiver 20 includes a heat dissipation system that allows heat produced from both the IC die 26 and the optical element 28 to dissipate, while eliminating heat transfer from the IC die 26 to the optical element 28, or reducing the heat transfer to levels that do not adversely affect the operation of the optical element 28 compared to conventional optical transceivers. The heat dissipation system can include an IC heat spreader 34 that can be mounted or otherwise coupled to the substrate 22. In particular, the IC heat spreader 34 can be mechanically coupled to the substrate 22 by any suitable attachment member, such as one or more fasteners, solder, adhesive, or the like. Thus, it can be said that the IC heat spreader 34 can be supported by or coupled to the substrate 22. Alternatively, the IC heat spreader 34 can be supported in any suitable alternative manner so as to be disposed at a location juxtaposed with the substrate 22 as desired. The IC heat spreader 34 can also be referred to as an electrical component heat spreader. For instance, the IC heat spreader 34 can be referred to as a driver heat spreader when incorporated into an optical transmitter. Alternatively or additionally, the IC heat spreader 34 can be referred to as a converter heat spreader when incorporated into an optical receiver, such that the electrical component is a current-to-voltage converter. Because the current-to-voltage converted can be configured as a TIA, the IC heat spreader 34 can also be referred to as a TIA heat spreader.

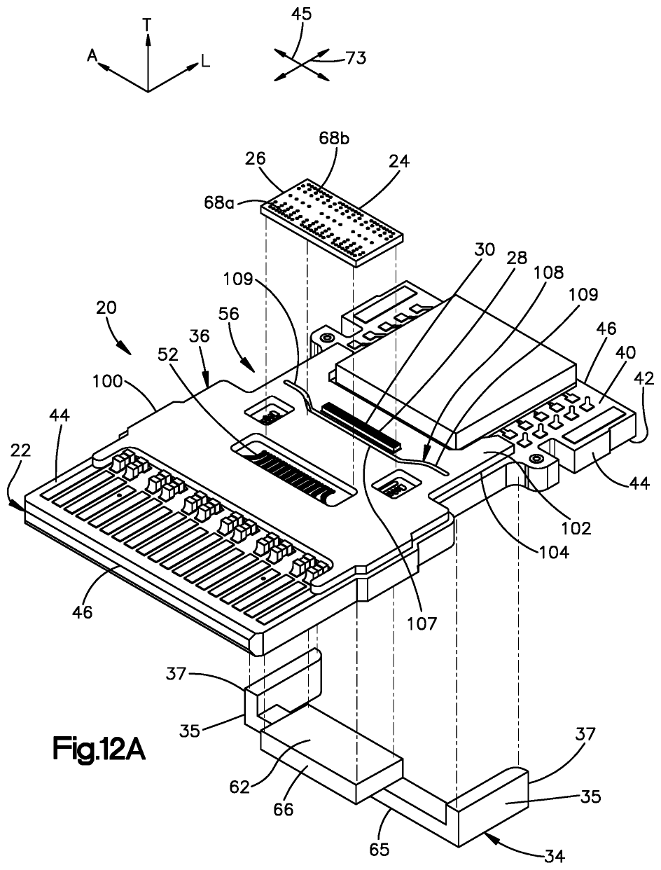

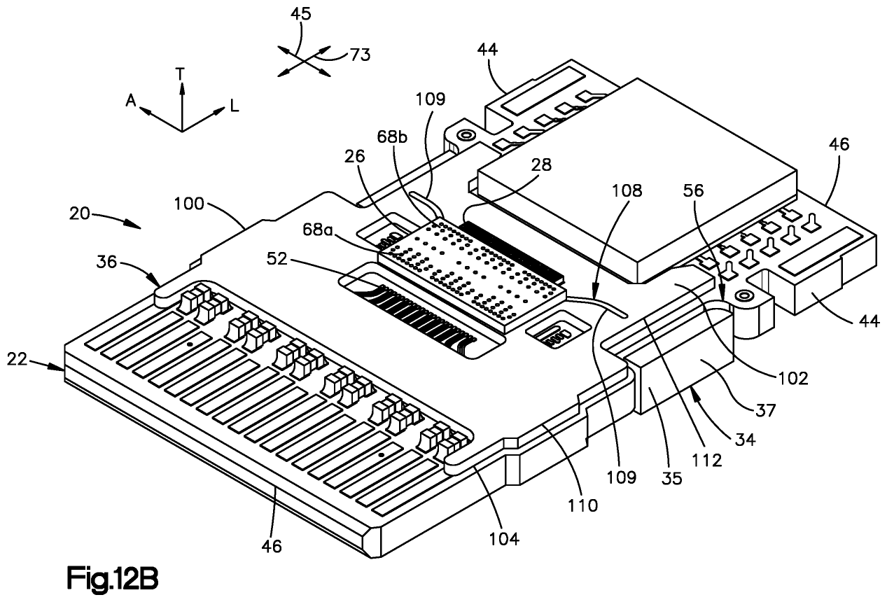

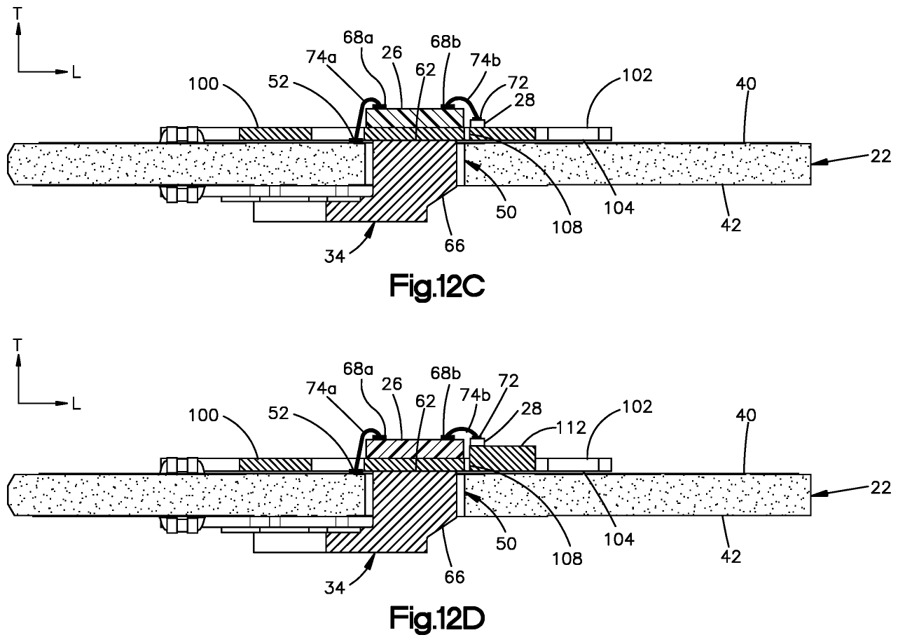

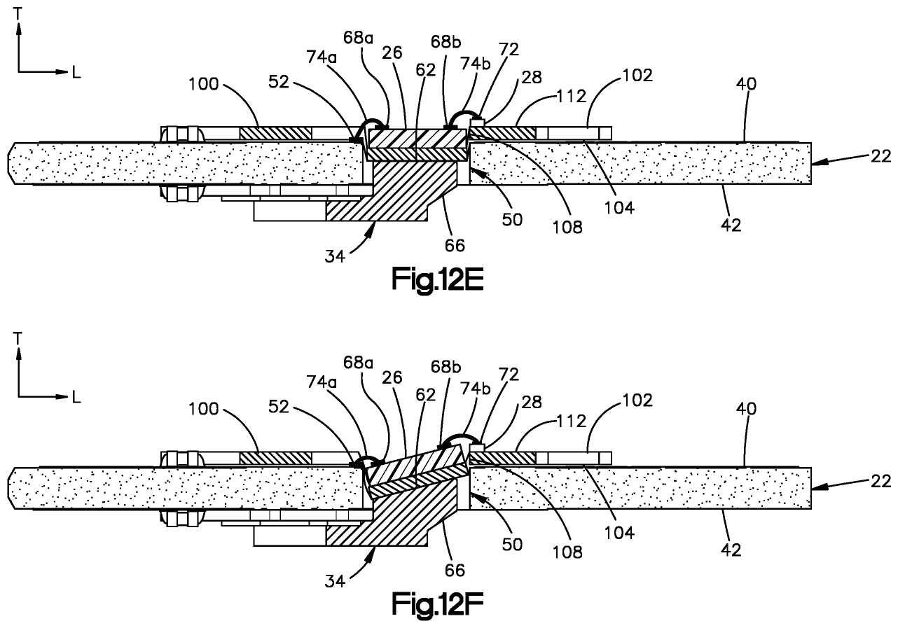

The IC heat spreader 34 can be in thermal communication with the IC die 26 and thus configured to dissipate heat from the IC die 26. For instance, the IC die 26 can be mounted on the IC heat spreader 34. The heat dissipation system can further include a thermal conductor 100 that is in thermal communication with the optical element 28. For instance, the optical element 28 can be mounted on thermal conductor 100. The thermal conductor 100 can be configured to dissipate heat from the optical element 28. In this regard, the thermal conductor 100 can be referred to as an optical element heat spreader 36 in certain examples. Thus, unless otherwise indicated, the terms “thermal conductor” and “optical element heat spreader” can be used interchangeably. In some examples as described below with reference to FIGS. 12A-12F, the IC die 26 can also be mounted onto the thermal conductor 100. The optical element heat spreader 36 can also be referred to as a light source heat spreader when incorporated into an optical transmitter. Alternatively or additionally, the optical element heat spreader 36 can also be referred to as a photodetector heat spreader when incorporated into an optical receiver. In one example, the thermal conductor 100 can be configured as a thermally conductive plate. The thermal conductor 100 can be disposed adjacent the IC heat spreader 34.

The IC heat spreader 34 and the thermal conductor 100 can be fabricated from a material having high thermal conductivity, such as metal or ceramic. In some embodiments the IC heat spreader 34 can have a coefficient of thermal expansion substantially matched to the coefficient of thermal expansion of the IC die 26. Similarly, the optical element heat spreader 36 can have a coefficient of thermal expansion substantially matched to the optical element 28. A non-limiting list of materials that may be used as the IC heat spreader 34 includes copper, copper tungsten, molybdenum, alumina, beryllia, silicon carbide, diamond, aluminum nitride, carbon nanotubes, boron nitride, graphite, silver, or any other material commonly used for applications requiring thermal dissipation. Similarly, a non-limiting list of materials that may be used as the thermal conductor 100 includes copper, copper tungsten, molybdenum, alumina, beryllia, silicon carbide, diamond, aluminum nitride, carbon nanotubes, boron nitride, graphite, silver, or any other material commonly used for applications requiring thermal dissipation. The IC heat spreader 34 can be made from the same material as the optical element heat spreader 36. Alternatively, the IC heat spreader 34 can be made from a different material than the optical element heat spreader 36. The IC heat spreader 34 may have a heterogeneous structure, such has having a diamond layer adjacent the IC die 26 to further assist in removing heat from the IC die 26. Similarly, the optical element heat spreader 36 may have a heterogeneous structure, such has having a diamond layer adjacent the optical element 28 to further assist in removing heat from the optical element 28.

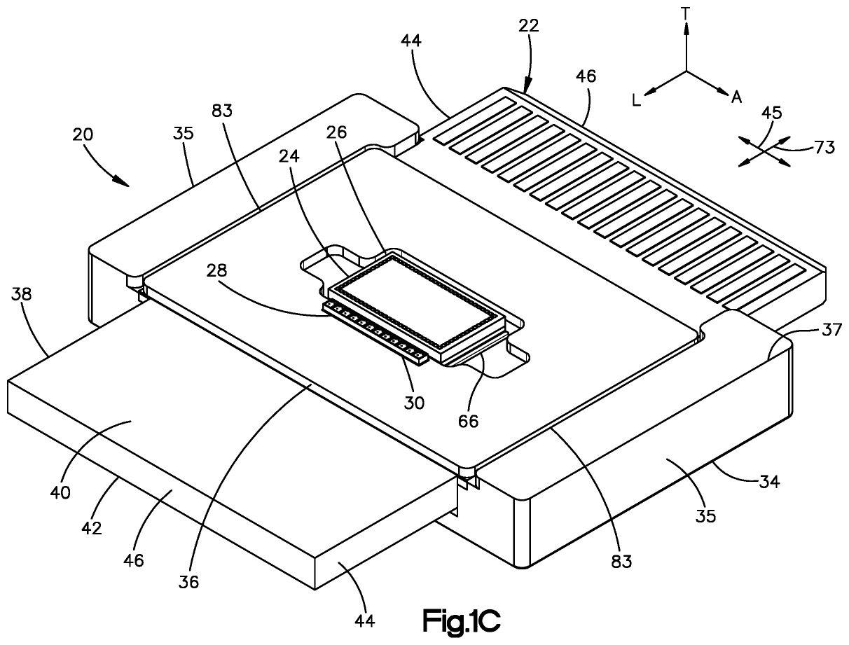

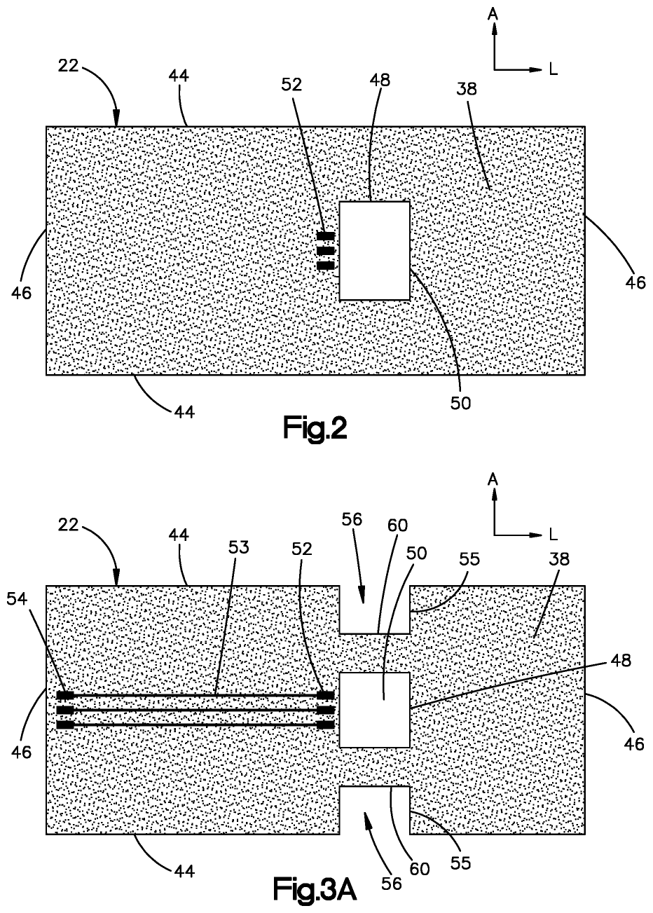

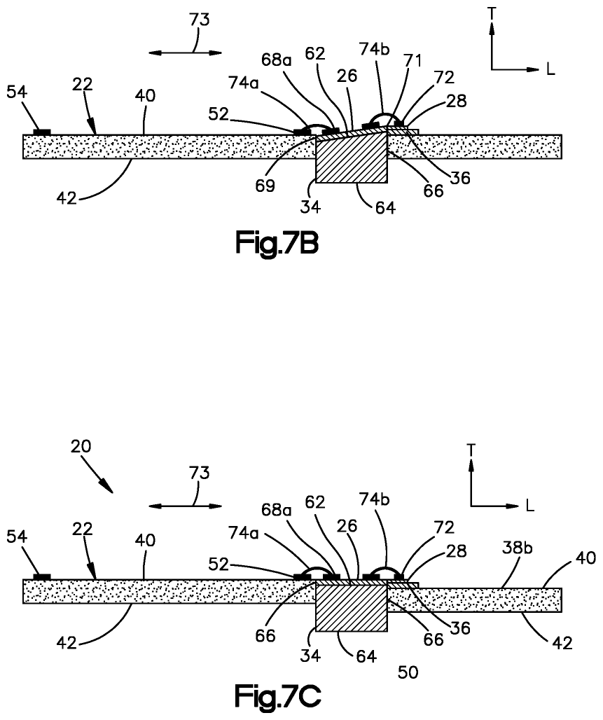

Referring now to FIGS. 1A-2, the transceiver substrate 22 is configured to support the integrated circuit and the optical element 28. For instance, the integrated circuit can be supported by the IC heat spreader 34 which, in turn, is supported by or otherwise coupled to the substrate 22. Thus, it can be said that the integrated circuit is supported by the substrate 22. Similarly, the optical element 28 can be supported by the optical element heat spreader 36 which, in turn, is supported by or otherwise coupled to the substrate 22. Thus, it can be said that the optical element is supported by the substrate 22. As described above, the integrated circuit can be configured as the IC die 26. Thus, the substrate 22 can be configured to support the IC die 26. The transceiver substrate 22 can be configured as a printed circuit board in one example. The transceiver substrate 22 has a substrate body 38 that defines a first or upper surface 40 and a second or lower surface 42 opposite the upper surface (see FIG. 7A) along a transverse direction T. The upper surface can be said to be disposed above the lower surface 42. Similarly, the lower surface 42 can be said to be disposed below the upper surface 40. Thus, the term “upper,” “upward,” “above,” and derivatives thereof as used herein can refer to a direction from the lower surface 42 to the upper surface 40 unless otherwise indicated. Similarly, the term “lower,” “downward,” “below,” and derivatives thereof as used herein can refer to a direction from the upper surface 40 to the lower surface 42 unless otherwise indicated. While the transverse direction T is illustrated as being a vertical direction in the drawings for clarity and convenience, it is recognized that the orientation of the transverse direction T may change during use.

The thermal conductor 100 defines a first or upper surface 102 and a second or lower surface 104 that is opposite the upper surface 102 along the transverse direction T. The thermal conductor 100 can be mounted to the upper surface 40 of the substrate 22 or otherwise coupled to or supported by the substrate 22 such that the lower surface 104 faces the upper surface 40 of the substrate 22. Thus, the term “upper,” “upward,” “above,” and derivatives thereof as used herein can refer to a direction from the lower surface 104 to the upper surface 102 unless otherwise indicated. Similarly, the term “lower,” “downward,” “below,” and derivatives thereof as used herein can refer to a direction from the upper surface 102 to the lower surface 104 unless otherwise indicated. While the transverse direction T is illustrated as being a vertical direction in the drawings for clarity and convenience, it is recognized that the orientation of the transverse direction T may change during use.

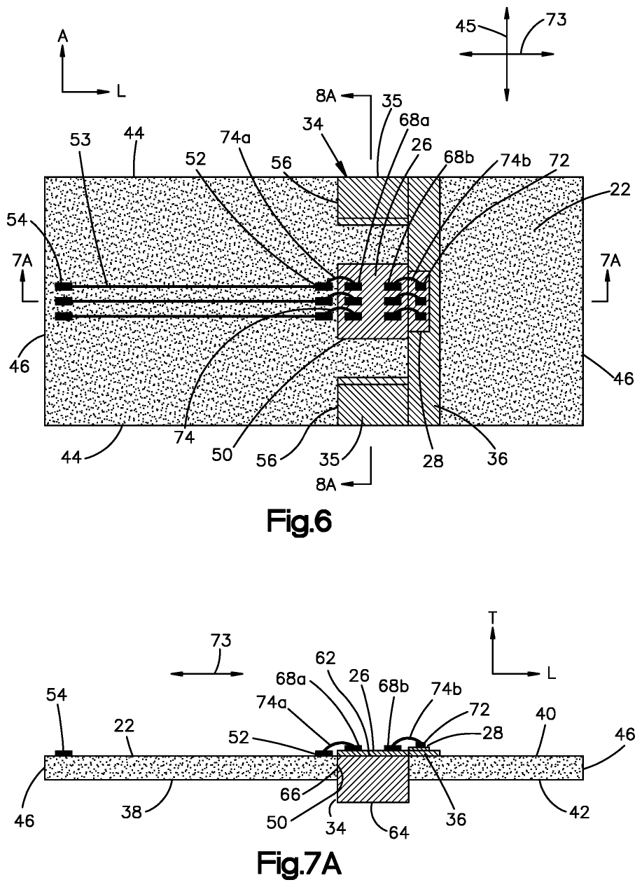

The substrate body 38 further defines two pairs of opposed first and second outer edges. In particular, the substrate body 38 can define opposed first and second outer lateral edges 44 that are spaced from each other along a lateral direction A that is oriented substantially perpendicular to the transverse direction T (see FIG. 6). The substrate body 38 further defines opposed first and second outer longitudinal edges 46 spaced from each other along a longitudinal direction L that is oriented substantially perpendicular to each of the transverse direction T and the lateral direction A. The substrate 22 defines a thickness measured along the transverse direction from the upper surface 40 to the lower surface 42. The substrate 22 defines a width measured along the lateral direction A from the one of the lateral edges 44 to the other of the lateral edges 44. The substrate 22 defines a length measured along the longitudinal direction L from the one of the longitudinal edges 46 to the other of the longitudinal edges 46. The thickness is less than both the width and the length. The width can be less than the length. The upper and lower surfaces 40 and 42 can each be oriented along respective planes that are defined by both the longitudinal direction L and the lateral direction A.

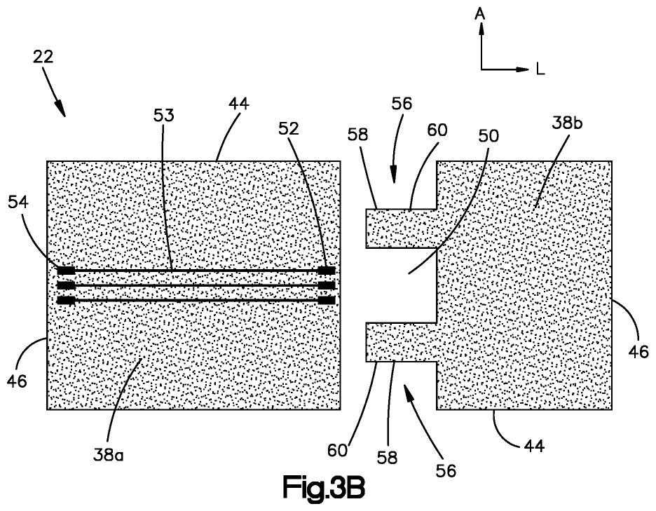

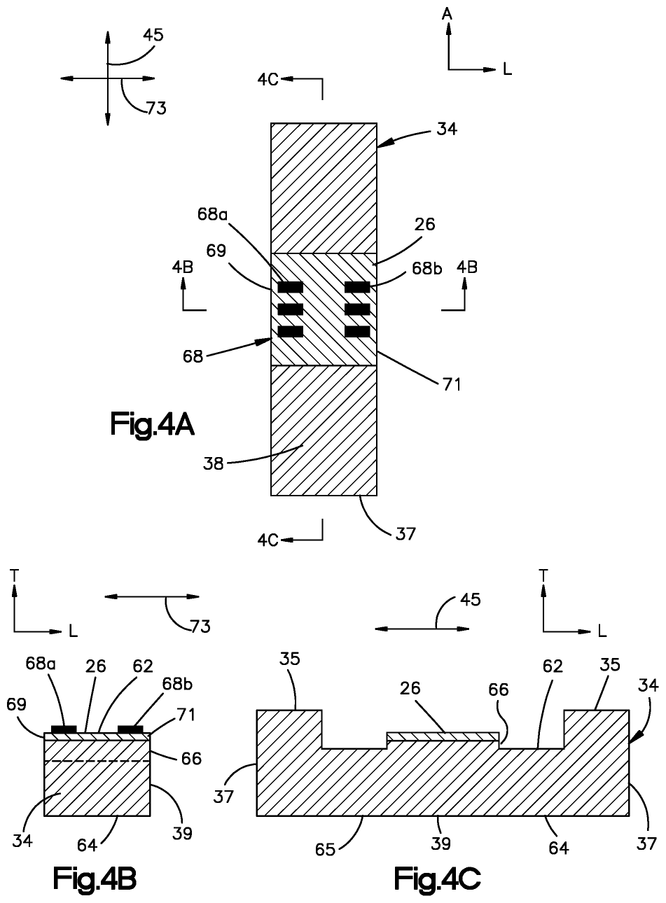

The IC heat spreader 34 can include at least one raised region 35. In one example, the raised region 35 can be disposed in its entirety below the substrate 22, as illustrated in FIGS. 1A-1B. Alternatively, as illustrated in FIG. 1C, the raised region can extend above the lower surface 42 of the substrate 22. For instance, the raised region 35 can extend above the upper surface 40 of the substrate 22. Thus, the raised regions 35 can extend to a height such that the upper surface 40 of the substrate 22 is disposed between the lower surface 42 and an upper surface 62 of the IC heat spreader 34 at the raised regions 35. In one example, the IC heat spreader 34 can include opposed raised regions. The raised regions 35 can be disposed at respective ends of the IC heat spreader 34. Thus, the raised regions 35 can be disposed at respective end regions 37 of the IC heat spreader 34. Thus, the end regions 37 can be said to define the raised regions 35. Alternatively, the end regions 37 can be devoid of raised regions, such that the upper surface 62 of the IC heat spreader 34 at the end regions is no higher than the upper surface 62 of the IC heat spreader 34 at an intermediate region that extends to a pedestal 66 (see FIGS. 4A-4C). The end regions 37 can define terminal ends of the IC heat spreader along a select direction 45. The end regions 37 can likewise be aligned with each other along the select direction 45. In some examples described in more detail below, the end regions 37 can be devoid of raised regions 35. The raised regions 35 can be spaced from each other along the select direction 45. The select direction 45 can be defined along a plane that is defined by the longitudinal direction L and the lateral direction A. The raised regions 35 can be disposed adjacent first and second opposed outer edges of the substrate 22, such that the outer edges are disposed between the raised regions 35 with respect to the select direction 45. In one example, none of the substrate 22 extends outward with respect to the raised regions 35 along the select direction 45. For instance, the first and second opposed outer edges can be continuously straight and linear along respective entireties of their lengths.

In one example, the IC heat spreader 34 can be oriented such that the select direction 45 is defined by the lateral direction A. Accordingly, the raised regions 35 can be spaced from each other along the lateral direction A. Thus, the raised regions 35 can likewise be aligned with each other along the lateral direction A. Thus, the first and second opposed outer edges can be defined by the lateral edges 44. The lateral edges 44 can be substantially continuously straight and linear from and to the opposed longitudinal edges 46, such that the laterally outermost edges of the raised regions 35 are disposed outboard with respect to respective entireties of the opposed lateral edges 44.

It should be appreciated, however, that the select direction 45 can be any suitable direction as desired. For instance, the select direction 45 can be defined by the longitudinal direction L. Accordingly, the raised regions 35 can be spaced from each other along the lateral direction A. Further, the raised regions 35 can be aligned with each other along the lateral direction L. Thus, the first and second opposed outer edges can be defined by the longitudinal edges 46. The longitudinal edges 46 can be substantially continuously straight and linear from and to the opposed lateral edges 44, such that the laterally outermost edges of the raised regions 35 are disposed outboard with respect to respective entireties of the opposed longitudinal edges 46.

With continuing reference to FIGS. 1A-2, the substrate 22 can define a mounting region 48 that is configured to support the integrated circuit. In one example, the mounting region 48 can be defined by a mounting aperture 50 that extends through the substrate body 38 from the upper surface 40 to the lower surface 42 along the transverse direction T. As described in more detail below, the IC die 26 may be mounted onto a portion of the IC heat spreader 34 that, in turn, is disposed in the mounting aperture 50. The mounting aperture 50 can have an enclosed perimeter along a plane that is defined by the longitudinal direction L and the lateral direction A. The enclosed perimeter can be defined by the substrate body 38.

The substrate 22 can further include at least one first electrical pad 52, such as a plurality of first electrical pads 52, disposed on the upper surface 40. In one example, the electrical pads 52, and all electrical pads described herein, can be configured as wire bond pads that are configured to attach to an electrical conductor without any additional filler or bonding agent such as solder, conductive epoxy, or the like. The electrical pads 52 can be disposed adjacent the mounting aperture 50. In particular, the electrical pads 52 can be disposed close to the perimeter of the mounting aperture 50 so as to minimize a distance of an electrical conductor that extends from the electrical pad 52 to the IC die 26 that is disposed in the mounting aperture 50 or aligned with the mounting aperture 50 along the transverse direction T, as is described in more detail below.

Further, the electrical pads 52 can define fiducial marks that facilitate accurate positioning of the mounting aperture 50 relative to the electrical pads 52. In particular, the mounting aperture 50 can be created in the transceiver substrate 22 at a location such that the perimeter of the mounting aperture 50 is spaced from the electrical pads 52 at a predetermined distance.

The final dimensions of the mounting aperture 50 can be formed in any suitable manner as desired so as to define the perimeter of the mounting aperture 50. For instance, the final dimensions of the mounting aperture 50 can be formed by laser routing, where a high energy laser beam is scanned across the surface of the substrate 22 to precisely remove material from the substrate body 38. Alternatively, the final dimensions of the mounting aperture 50 can be formed by waterjet cutting, conventional routing, or any suitable alternative fabrication technique. Certain fabrication methods provide for more accurate dimensional tolerance than can be obtained with convention mechanical routing methods. For example, the dimensions of the mounting aperture 50 along the lateral direction A and the longitudinal direction L can be fabricated to within ±25 microns (±0.001″) using laser routing. Similarly the distance between the perimeter of the mounting aperture 50 and the electrical pads 52 may have a tolerance of ±25 microns (±0.001″). The distance between the from the electrical pad 52 to the mounting aperture 50 may be in a range from approximately 50 microns to approximately 300 microns, such as from approximately 75 microns to approximately 200 microns, and in particular approximately 100 microns (0.004″). It is appreciated that the terms “substantially” and “approximately” as described herein recognize that various distances and measurements may not always be exact for a number of reasons, including manufacturing tolerances. It should further be appreciated that the distances and measurements provided herein are by way of example, and that the present disclosure is not to be construed as limited to these examples unless otherwise indicated herein. For instance, the terms “substantially” and “approximately” as used herein can include variations of up to 10% of the stated value. The mounting aperture 50 can be sized so that the IC die 26 fits tightly in the mounting aperture 50 with a minimal gap between the IC die 26 and the perimeter of the mounting aperture 50, particularly in areas adjacent the electrical pads 52. By way of example, a representative size for the IC die 26 and mounting aperture 50 may be a width of approximately 3 mm and length of approximately 5 mm, although both smaller and larger IC dies and mounting apertures may be used.

Referring now to FIG. 3A, the substrate 22 can include at least one second electrical pad 54, such as a plurality of second electrical pads 54. The second electrical pads 54 can be disposed on the upper surface 40 of the substrate 22. It should be appreciated, of course, that the first and second electrical pads 52 and 54 can be carried by any surface of the substrate 22, including the upper surface 40 and the lower surface 42. The second electrical pads 54 can be disposed distal with respect the mounting aperture 50 and the IC die 26. In this regard, the first electrical pads 52 of the substrate 22 can be referred to as proximal electrical pads, as they are disposed proximal to the mounting aperture 50 and the IC die 26. The second electrical pads 54 of the substrate 22 can be referred to as distal electrical pads. The second electrical pads 54 can be disposed adjacent one of the outer edges of the substrate 22. For instance, the second electrical pads 54 can be disposed adjacent one of the longitudinal edges 46. The substrate 22 can include one or more electrical traces 53 carried by the substrate body 38 that are in electrical communication with respective ones of both the proximal electrical pads 52 and the distal electrical pads 54, respectively. Thus, the substrate 22 can be configured to transmit high speed electrical signals between the one or more second electrical pads 54 and the one or more proximal electrical pads 52.

The second electrical pads 54 can be placed in electrical and mechanical contact with an electrical connector. The electrical connector can be configured as an edge card connector. In one example, the edge card connector can be as UEC5 connector manufactured by Samtec Inc. having a principal place of business in New Albany, Ind. Thus, when the electrical connector is in electrical communication with the distal electrical pads 54, and the IC die 26 is placed in electrical communication with the proximal electrical pads 52, the electrical connector is placed in electrical communication with the IC die 26.

As illustrated in FIG. 3B, the substrate 22 can define at least one heat transfer region 55. In particular, the heat transfer region 55 can be configured to facilitate heat transfer through the substrate 22 along the transverse direction T. The heat transfer region 55 is offset from the mounting region 48 along one or both of the longitudinal direction L and the lateral direction A. Thus, it can be said that the heat transfer region 55 is offset from the mounting region 48 along a direction that extends along a plane that, in turn, is defined by the upper surface 40 of the substrate 22. Similarly, it can be said that the heat transfer region 55 is offset from the mounting region 48 along a direction that extends along a plane that, in turn, is defined by the lower surface 42 of the substrate 22. The direction can thus be defined by one or both of the longitudinal direction L and the lateral direction A. In one example, the at least one heat transfer region 55 can include at least one opening that extends through the substrate 22 along the transverse direction T. The opening can be configured as a notch 56 that extends into a respective at least one of the first and second opposed outer edges along the select direction. For instance, the substrate 22 can define a pair of notches 56 that extend into respective ones of the first and second opposed outer edges along the select direction. As will be appreciated from the description below, the IC heat spreader 34 can extend into the at least one notch 56, such as each of the notches 56, to transfer heat through the substrate 22 upward along the transverse direction T.

Thus, the substrate 22 can define a respective recessed edge 60 disposed between adjacent segments of the outer edges of the substrate 22 to define each notch 56. The notches 56 can be spaced from each other along the select direction. For instance, the notches 56 can be aligned with each other along the select direction. When the notches 56 extend into the substrate body 38 along the lateral direction A, the width of the substrate 22 along the lateral direction A from and to the first and second opposed lateral edges 44 is greater than the distance from and to the opposed recessed edges 60 along the lateral direction A.

In one example, the notches 56 have a depth along the select direction 45 that is greater than or equal to respective lengths of the respective raised regions 35 along the select direction. As a result, an entirety of the IC heat spreader 34 can be disposed between the opposed first and second outer edges with respect to the select direction. Alternatively, opposed outer surfaces of the IC heat spreader 34 along the select direction 45 can be substantially aligned with the opposed edges of the substrate 22 that are opposite each other along the select direction. Regardless of whether the opposed first and second outer edges are substantially straight and continuous or notched, the IC heat spreader 34 provide a thermal path having a low thermal resistance between the upper surface 40 of the substrate 22 and the lower surface 42 of the substrate.

As described above, in one example the select direction 45 can be defined by the lateral direction A. Thus, the notches 56 can extend into the outer lateral edges 44. Alternatively, the select direction 45 can be defined by the longitudinal direction L. Thus, the notches 56 can extend into the outer longitudinal edges 46.

As illustrated in FIGS. 1A-2, the substrate body 38 can be a single monolithic substrate body that defines respective entireties of both the opposed lateral edges 44 and the opposed longitudinal edges 46. Alternatively, as referring now to FIG. 3B, the substrate 22 can be a composite substrate that includes a plurality (i.e., at least two) substrate bodies that in combination define the entireties of both the opposed lateral edges 44 and the opposed longitudinal edges 46. For instance, the substrate 22 can include first and second separate substrate bodies 38a and 38b that, in combination, define the respective entireties of both the opposed lateral edges 44 and the opposed longitudinal edges 46. Thus, it can be said that the substrate 22 can include at least one substrate body that defines respective entireties of both the opposed lateral edges 44 and the opposed longitudinal edges 46.

The first substrate body 38a can define the proximal and distal electrical pads 52 and 54, and the electrical trace that extends between the proximal and distal electrical pads 52 and 54. The first and second substrate bodies 38a and 38b can combine to define the mounting aperture 50. For instance, one of the first and second substrate bodies 38a and 38b can define opposed first and second legs 58 that define respective portions of the outer perimeter of the mounting aperture 50 when the first and second substrate bodies 38a and 38b are joined together. The legs 58 can be defined by one of the first and second substrate bodies 38a and 38b. Alternatively, one of the legs 58 can be defined by the first substrate body 38a and the other of the legs 58 can be defined by the second substrate body 38b. It can thus be said that each of the first and second substrate bodies 38a and 38b can define at least a portion of the mounting aperture 50.

Similarly, the substrate 22 including the first and second substrate bodies 38a and 38b can also define the notches 56. In particular, the notches 56 can be defined by at least one of the first and second substrate bodies 38a and 38b. For instance, the second substrate body 38b can define opposed recessed edges 60 that define respective innermost boundaries of the notches 56. Alternatively, the first substrate body 38a can define the recessed edges 60. Alternatively still, the first substrate body 38a can define one of the recessed edges 60, and the second substrate body 38b can define the other of the recessed edges 60. Alternatively still, each of the first and second substrate bodies 38a and 38b can define a respective portion of at least one or both of the recessed edges 60. In another example, the composite substrate 22 can be devoid of notches.

Referring now to FIGS. 4A-4C, the IC heat spreader 34 defines an intermediate region 39 that extends between the end regions 37. For instance, the intermediate region 39 can extend from one of the end regions 37 to the other of the end regions 37. The IC heat spreader 34 defines a first or upper surface 62 and a second or lower surface 64 opposite the upper surface 62 along the transverse direction T. The IC die 26 can be mounted to the upper surface of the IC heat spreader 34. In particular, the IC die 26 can be mounted to the upper surface of the IC heat spreader 34 at the intermediate region 39.

In one example, the IC heat spreader 34 can define a base 65 and a pedestal 66 that extends up from the base 65. The base 65 can be elongate along the select direction 45. The raised regions 35 can also extend up from the base 65. Thus, the upper surface 62 of the IC heat spreader 34 at the pedestal 66 can be disposed above the upper surface 62 of the IC heat spreader 34 at the intermediate portion at a location between the pedestal 66 and each of the end regions 37. The upper surface 62 of the IC heat spreader 34 at the intermediate portion can extend below the lower surface of the substrate 22. The IC die 26 can be mounted to the IC heat spreader 34 with a thermally conductive epoxy, solder, or any suitable alternative attachment mechanism that provides a low thermal resistance path between the IC die 26 and the IC heat spreader 34. For instance, the IC die can be mounted to the pedestal 66. In particular, the IC die 26 can be mounted to the pedestal 66 at the upper surface 62. Even though the IC die 26 is disposed above the upper surface of the substrate 22, the IC die 26 can still be said to be mounted at the mounting region 48, as the IC die 26 is mounted to structure that extends through the mounting aperture 50. It can thus be said that at least one of the pedestal 66 and the IC die 26 extends at least into or through the mounting aperture 50.

Referring again to FIGS. 1A-1B, the thermal conductor 100 can further include a plate aperture 106 that extends therethrough from the upper surface 102 to the lower surface 104. The plate aperture 106 can be sized to receive one or both of the pedestal 66 of the IC heat spreader 34 and the IC die 26. As described above with respect to the mounting aperture 50 of the substrate 22, the plate aperture 106 can be sized so that the IC die 26 fits tightly in the plate aperture 106 with a minimal gap between the IC die 26 and the perimeter of the plate aperture 106, particularly in areas adjacent the electrical pads 52 of the substrate 22. Thus, the aperture 106 can be substantially aligned with the mounting aperture 50 of the substrate 22 along the transverse direction T. The plate aperture 106 can define an outer perimeter that is enclosed by the thermal conductor 100 along a plane that is defined by the longitudinal direction L and the lateral direction A. Alternatively, one or more ends can be open along the plane that is defined by the longitudinal direction L and the lateral direction A.

The pedestal 66, the remainder of the intermediate region 39, and the end regions 37, and the raised regions 35 can all be monolithic with each other in one example. Alternatively, the IC heat spreader 34 can be made of separate components attached to each other. For instance, one or more up to all of the pedestal 66, the remainder of the intermediate region 39, and the end regions 37, and the raised regions 35 can define separate structures that are attached to each other and placed in thermal communication with each other.

The IC die 26 can have any suitable thickness along the transverse direction. As one non-limiting representative example, the thickness of the IC die can be approximately 250 microns, but thinner or thicker dies may be used. The IC die 26 and the pedestal 66 can define respective widths. In one example, the width of the IC die 26 can be greater than the width of the pedestal 66. Accordingly, the IC die 26 can overhang one or both opposed edges of the pedestal 66 that define the width of the pedestal 66. The respective widths can be defined along the lateral direction A. Alternatively, the respective widths can be defined along the longitudinal direction L.

The IC die 26 can include at least one IC electrical pad 68, such as a plurality of IC electrical pads 68, disposed on the upper surface of the IC die 26. Thus, the IC electrical pads 68 can extend out from the upper surface of the IC die 26 along the transverse direction T. In one example, the IC electrical pads 68 can be configured as wire bond pads. The IC electrical pads 68 can include a first group 68a of at least one IC electrical pad 68 disposed adjacent the first at least one electrical pad 52 of the substrate 22. The first group 68a can include a plurality of IC electrical pads 68. The first group 68a of IC electrical pads 68 can be disposed adjacent a first edge 69 of the IC die 26. For instance, the IC electrical pads 68 of the first group 68a can be aligned with each other along the first edge 69 of the IC die 26. In one example, the electrical pads 68 of the first group 68a can be spaced from the first edge 69 with respect to a distance along a plane defined by the longitudinal direction L and the lateral direction A that ranges from approximately 10 to approximately 200 microns, such as from approximately 20 to approximately 50 microns.

The IC electrical pads 68 can include a second group 68b of at least one IC electrical pad 68 disposed adjacent the optical element 28. The second group 68b can include a plurality of IC electrical pads 68. The second group 68b of IC electrical pads 68 can be disposed adjacent a second edge 71 of the IC die 26. For instance, the IC electrical pads 68 of the second group 68b can be aligned with each other along the second edge 71 of the IC die 26. The first and second edges 69 and 71 can be spaced from each other along a plane that is defined by the longitudinal direction L and the lateral direction A. For instance, the first and second edges 69 and 71 can be opposite each other. In one example, the first and second edges 69 and 71 can be opposite each other along the longitudinal direction L. In another example, the first and second edges 69 and 71 can be opposite each other along the lateral direction A. In one example, the electrical pads 68 of the second group 68b can be spaced from the second edge 71 a distance ranging from approximately 10 to approximately 200 microns, such as from approximately 20 to approximately 50 microns.

As described above, the IC heat spreader 34 can include the opposed raised regions 35 disposed such that the pedestal 66 is disposed between the opposed raised regions 35. The raised regions 35 and the pedestal 66 can have respective heights along the transverse direction T. The height of the raised region 35 can be greater than the height of the pedestal 66. Thus, the upper surface 62 of the IC heat spreader 34 at the raised regions 35 can be disposed above the upper surface 62 of the IC heat spreader 34 at the pedestal 66. Alternatively, height of the raised region 35 can be substantially equal to the height of the pedestal 66. Thus, the upper surface 62 of the IC heat spreader 34 at the raised regions 35 can be substantially coplanar with the upper surface 62 of the IC heat spreader 34 at the pedestal 66 along a plane defined by the longitudinal direction L and the lateral direction A. Alternatively still, the height of the raised region 35 can be less than the height of the pedestal 66. Thus, the upper surface 62 of the IC heat spreader 34 at the raised regions 35 can be disposed below the upper surface 62 of the IC heat spreader 34 at the pedestal 66.

The term “substantially coplanar” as used herein can apply to structure that lie in the same plane, or are within a distance of lying in the same plane. The distance can be up to 200 microns in one example. For instance, the distance can be 100 microns. In particular, the distance can be 50 microns. Further, unless otherwise indicated, the terms “substantially coplanar” and “coplanar” are used herein as along a plane that is defined by the longitudinal direction L and the lateral direction A. Thus, the terms “substantially coplanar” and “coplanar” are likewise used herein as along a plane that is defined by the select direction 45 and the direction 73 that is perpendicular to the select direction. It should be further appreciated that components that are substantially coplanar with each other along a plane defined by the longitudinal direction L and the lateral direction A can also be said to lie at substantially the same position in the transverse direction T. For instance, unless otherwise indicated, the term “substantially coplanar” can include an offset along the transverse direction T of up to approximately 100 microns. For instance, the offset can be approximately 50 microns. It should also be appreciated that the term “substantially coplanar” can include coplanar, meaning an offset of no more than 10 microns. In one example, “coplanar” can mean that there is no offset along the transverse direction T.

When the IC die 26 is mounted on the pedestal 66, the upper surface 62 of the IC heat spreader 34 at the raised regions 35 can be disposed above the upper surface 62 of the IC die 26. In another example, the upper surface 62 of the IC heat spreader 34 at the raised regions 35 can be substantially coplanar with the upper surface of the IC die 26. Alternatively still, the upper surface 62 of the IC heat spreader 34 at the raised regions 35 can be below the upper surface of the IC die 26. In still other example, as described above, the IC heat spreader 34 can be devoid of the raised regions 35.

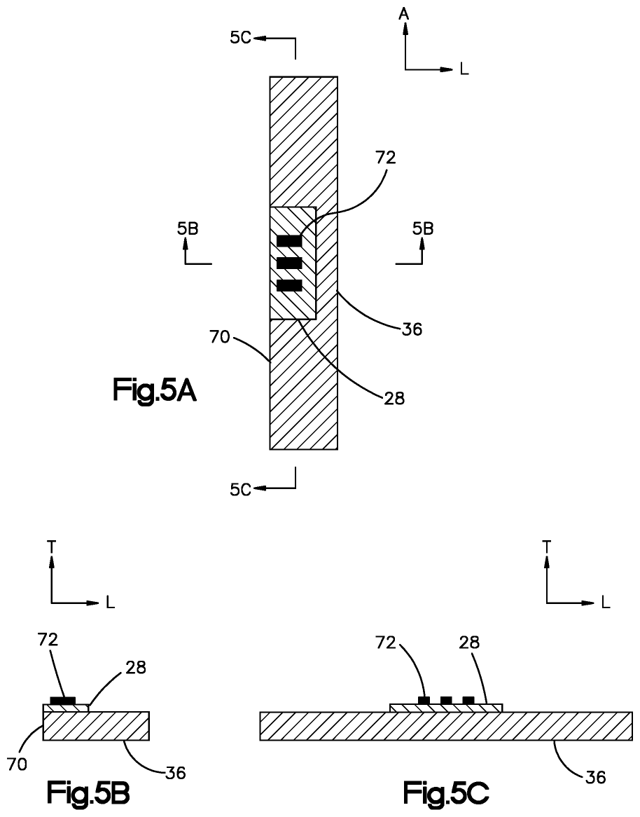

Referring now to FIGS. 5A-5C, the optical element 28 can be mounted to the upper surface 41 of the optical element heat spreader 36. In particular, the optical element 28 can be mounted to the optical element heat spreader 36 using a thermally conductive epoxy, solder, or any suitable attachment mechanism that provides a low thermal resistance path between the optical element 28 and the optical element heat spreader 36. By way of example, representative dimensions for the optical element 28 may be approximately 120 microns by approximately 300 microns by approximately 3 mm, although both smaller and larger optical elements may be used.

The optical element 28 can be mounted along a select edge 70 of the optical element heat spreader 36. The select edge 70 can define a portion of an outer perimeter of the optical element 28 in a plane that is defined by the longitudinal direction L and the lateral direction A. For instance, the select edge 70 can define a boundary of the outer perimeter of the optical element 28 with respect to the longitudinal direction L. Alternatively, the select edge 70 can define a boundary of the outer perimeter of the optical element 28 with respect to the lateral direction A. The select edge 70 can face the second edge 71 of the IC heat spreader 34. The optical element 28 can include at least one optical element electrical pad 72, such as a plurality of optical element electrical pads 72. For instance, the optical element electrical pads 72 can be disposed on the upper surface of the optical element 28. The optical element electrical pads 72 can be disposed along the select edge 70. For instance, the optical element electrical pads 72 can be aligned with each other along the select edge 70. In one example, the optical element electrical pads 72 can be spaced from the select edge 70 a distance along a plane that is defined by the longitudinal direction L and the lateral direction A that ranges from approximately 10 to approximately 200 microns, such as from approximately 20 to approximately 50 microns.

By way of example, representative dimensions for the optical element heat spreader 36 can be approximately 3 mm by approximately 10 mm along the plane defined by the longitudinal direction L and the lateral direction A, although both smaller and larger optical elements may be used. In one example, the optical element heat spreader 36 can be a rectangular parallelepiped. The optical element heat spreader may be fabricated from a material having high thermal conductivity such as were previously described relative to the IC heat spreader 34. The optical element heat spreader 36 can have a coefficient of thermal expansion substantially matched to the coefficient of thermal expansion of the optical element 28. In one example, the optical element 28 and the optical element heat spreader 36 can be fabricated from the same material. Alternatively, the optical element 28 and the optical element heat spreader 36 can be fabricated from different materials. The optical element heat spreader 36 may have a heterogeneous structure, such has having a diamond layer that is disposed adjacent the optical element 28 to further assist in removing heat from the optical element 28.

Referring also to FIG. 6, the base 65 of the IC heat spreader 34 can extend along the lower surface 42 of the substrate 22. The pedestal 66 can extend from the base 65 at least into the mounting aperture 50 along the transverse direction T. For instance, in one example, the pedestal 66 can extend from the base 65 through the mounting aperture 50. Thus, a portion of the upper surface 62 of the IC heat spreader 34 can be disposed above the upper surface 40 of the substrate 22. Alternatively, the upper surface 62 of the IC heat spreader 34 can be disposed below the upper surface 40 of the substrate 22. Alternatively still, the upper surface 62 of the IC heat spreader 34 can be substantially coplanar with the upper surface 40 of the substrate 22. Thus, when the IC die 26 is mounted to the pedestal 66, an entirety of the IC die 26 can be disposed above the upper surface 40 of the substrate 22. Alternatively, the upper surface 40 of the substrate 22 can be aligned with a portion of the IC die 26 with respect to a plane that is defined by the longitudinal direction L and the lateral direction A.

The end regions 37 of the IC heat spreader 34 can be aligned with respective ones of the notches 56 of the substrate 22 along the transverse direction T. Thus, in one example, the IC heat spreader 34 does not extend out with respect to the substrate 22 with respect to a plane that is defined by the lateral direction A and the longitudinal direction L. Alternatively, the IC heat spreader 34 can extend from the notch 56 to a location spaced outward with respect to the substrate 22 with respect to a plane that is defined by the lateral direction A and the longitudinal direction L. Alternatively, as illustrated in FIGS. 1-2, if the substrate 22 is not notched, the end regions 37 of the IC heat spreader can extend out with respect to the substrate 22 along a plane that is defined by the lateral direction A and the longitudinal direction L. In one example, the end regions 37 of the IC heat spreader can extend outward with respect to a respective one of the outer lateral edges 44 of the substrate 22 along the lateral direction A. Thus, the raised regions 35 can likewise be disposed outward with respect to the substrate 22 with respect to the plane that is defined by the lateral direction A and the longitudinal direction L. For instance, the raised regions 35 can be disposed outward with respect to a respective one of the outer lateral edges 44 of the substrate 22 along the lateral direction A. Thus, the end region 37 and the raised regions 35 can be disposed outside a footprint defined by the substrate 22.

The optical element heat spreader 36 can be mounted onto or otherwise coupled to the substrate 22. In one example, the optical element heat spreader 36 can be mounted onto the upper surface 40 of the substrate 22. For instance, the optical element heat spreader 36 can be mechanically attached to the substrate 22 by any suitable attachment member, such as one or more fasteners, solder, adhesive, or the like. Alternatively, the optical element heat spreader 36 can be placed over the upper surface 40 of the substrate 22 and not be mechanically attached to the substrate 22. Thus, at least a portion of the optical element heat spreader 36 can extend along the upper surface 40 of the substrate 22. At least a portion of the IC heat spreader 34 described above can extend along the lower surface 42 of the substrate 22. Thus, the substrate 22 can be disposed between the at least a portion of the optical element heat spreader 36 and the at least a portion of the IC heat spreader 34 along the transverse direction. Accordingly, the substrate 22 can thermally isolate the at least a portion of the optical element heat spreader 36 from the at least a portion of the IC heat spreader 34. In one example, the at least a portion of the optical element heat spreader 36 can define a majority of the at least a portion of the optical element heat spreader 36. For instance, the at least a portion of the optical element heat spreader 36 can define an entirety of the optical element heat spreader 36. Similarly, the at least a portion of the IC heat spreader 34 can define a majority of the at IC heat spreader 34 can define an entirety of the IC heat spreader 34.

The optical element heat spreader 36 may have a length along the select direction 45 that is substantially equal to the length of the IC heat spreader 34 along the select direction 45. The IC heat spreader 34 and the optical element heat spreader 36 may have a substantially equal length along the select direction 45. The length may be substantially equal to the width of the substrate 22 along the select direction 45 from and to the opposing edges that are opposite each other along the select direction 45. Thus, the edges can be defined by the opposed first and second outer lateral edges 44. Alternatively, the edges can be defined by the opposed first and second longitudinal edges 46. If the substrate 22 includes the notches 56, the width of the substrate 22 can be defined at a location adjacent the notches 56 (and thus the width is not defined by the recessed edges 60).

Thus, the IC heat spreader may 34 and the optical element heat spreader 36 can be positioned relative to the substrate 22 such that the overall width of the optical transceiver 20 along the lateral direction A is defined by the maximum width of the substrate 22. For instance, neither of the IC heat spreader 34 and the optical element heat spreader 36 extends past a footprint of the substrate 22 along a plane that is defined by the longitudinal direction L and the lateral direction A. In one example, neither of the IC heat spreader 34 and the optical element heat spreader 36 extends past a footprint of the substrate 22 along the select direction 45. Thus, in one example, neither of the IC heat spreader 34 nor the optical element heat spreader extends laterally outboard of the lateral edges 44 of the substrate 22, and neither of the IC heat spreader nor the optical element heat spreader 36 extends longitudinally outboard of the longitudinal edges 46 of the substrate 22. When the substrate 22 includes the notches 56, the IC heat spreader 34 can extend outward of the recessed edges 60 of the substrate 22 along the select direction 45. Thus, end regions 37 of the IC heat spreader 34 can be substantially aligned with the notches 56 along the transverse direction T. When the IC heat spreader includes the raised regions 35, the raised regions 35 can be disposed in respective ones of the notches 56. For example, the raised regions 35 can substantially fill the notches 56.

When the substrate 22 does not include the notches 56 in certain examples, the footprint of the optical transceiver 20 along the plane defined by the longitudinal direction L and the lateral direction A can be partially defined by one or both of the IC heat spreader 34 and the optical element heat spreader 36. For instance, one or both of and the IC heat spreader 34 and the optical element heat spreader 36 can extend outward of the outer edges of the substrate 22 that are spaced from each other along the select direction 45.

Referring now to FIG. 7A, the IC heat spreader 34 and the optical element heat spreader 36 can be separate structures that are spaced from each other along a plane that is defined by the longitudinal direction L and the lateral direction A. In particular, the IC heat spreader 34 can be spaced from the optical element heat spreader 36 along the plane that is defined by the longitudinal direction L and the lateral direction A so as to define a gap 83 therebetween (see FIGS. 1A-1C). Thus, the IC heat spreader 34 and the optical element heat spreader 36 can be substantially thermally isolated from each other along both the select direction 45 and the direction 73 that is perpendicular to the select direction 45. Thus, in one example, the IC heat spreader 34 can be free from mechanical contact from the optical element heat spreader 36. For instance, air can thermally insulate the IC heat spreader 34 from the optical element heat spreader 36. It should be appreciated, of course, that any alternative thermal insulator can be disposed between the IC heat spreader 34 and the optical element heat spreader 36 as desired. It should be appreciated that this disclosure is not intended to be limited to examples whereby the IC heat spreader 34 and the optical element heat spreader 36 are isolated from each other in their entireties. For instance, a minimal amount of the IC heat spreader 34 can be in mechanical contact or thermal communication with the optical element heat spreader 36. In one example, one or both of the end regions 37 of the IC heat spreader 34 can contact the thermal conductor 100. Alternatively or additionally, one or both of the end regions 37 of the IC heat spreader 34 can be spaced from the thermal conductor 100. Thus, it can be said that the IC heat spreader 34 is at least substantially thermally isolated from the optical element heat spreader 36.

As a result of the at least substantial thermal isolation between the IC heat spreader 34 and the optical element heat spreader 36, the heat generated by the IC die 26 can be dissipated without traveling to the optical element 28 in an amount sufficient to substantially affect the operation of the optical element 28. Otherwise stated, the IC heat spreader 34 can define a surface on which the IC die 26 is mounted, and which receives thermal energy from the IC die 26 and substantially does not receive thermal energy from the optical element 28. That is, in one example, more of the heat generated by the IC die 26 is dissipated through the IC heat spreader 34 than through the optical element heat spreader 36. For instance, at least 75% of the heat generated by the IC die 26 is dissipated through the IC heat spreader 34 than through the optical element heat spreader 36.

With continuing reference to FIG. 7A, the transceiver 20 can include at least one first electrical conductor 74a that is electrically connected at a first end to a respective one of the at least one first electrical pad 52 of the substrate 22, and at a second end to a respective one of the first group 68a of at least one IC electrical pad 68. For instance, the transceiver 20 can include a plurality of first electrical conductors 74a that are electrically connected at a first end to a respective one of the plurality of first electrical pads 52 of the substrate 22, and at a second end to a respective one of the first group 68a of the plurality of IC electrical pads 68. The transceiver 20 can include at least one second electrical conductor 74b that is electrically connected at a first end to a respective one of the second group 68b of at least one IC electrical pad 68, and at a second end to the at least one optical element electrical pad 72. For instance, the transceiver 20 can include a plurality of second electrical conductors 74b that are electrically connected at a respective first end to a respective one of the second group 68b of the plurality of IC electrical pads 68, and at a second end to a respective one of the plurality of optical element electrical pads 72. In one example, the electrical conductors 74a and 74b can be defined by one or more of electrically conductive wires or ribbons that are bonded to pads using well known wire and/or ribbon bonding techniques.

When the IC heat spreader 34 and the optical element heat spreader 36 are coupled to the substrate 22, the electrical pads 68 of the second group 68b of IC electrical pads can be offset with respect to the optical element electrical pads 72 along the transverse direction T. In particular, it is recognized that it may be desirable to position the upper surface of the IC die between the upper surface 40 of the substrate 22 and the upper surface of the optical element 28 with respect to the transverse direction T. As a result, the first electrical pads 52 of the substrate 22 can be offset with respect to the first group 68a of IC electrical pads 68 along the transverse direction T, and the second group 68b of IC electrical pads 68 can be offset with respect to the optical element electrical pads 72 along the transverse direction T. For instance, the first and second groups 68a and 68b of electrical pads of the IC die 26 can be disposed between the first electrical pads 52 of the substrate 22 and the optical element electrical pads 72 along the transverse direction T.

For instance, it is recognized that the optical element heat spreader 36 is mounted to the upper surface 40 of the substrate 22, and the optical element 28 is mounted to the upper surface 41 of the optical element heat spreader 36. Thus, the upper surface 41 of the optical element heat spreader 36 is offset with respect to the upper surface 40 of the substrate 22 along the transverse direction. In particular, the upper surface 41 of the optical element heat spreader 36 can be spaced above the upper surface 40 of the substrate 22. In order to maintain the lengths of the first and second electrical conductors 74a and 74b substantially equal to each other (and not increasing one of the electrical conductors 74a and 74b to an undesirable length), it can be desirable to position the upper surface of the IC die 26 at a location between the upper surface 40 of the substrate 22 and the upper surface of the optical element 28 with respect to the transverse direction T. It can thus be said that the upper surface of the IC die 26 is stepped with respect to each of the upper surface 40 of the substrate 22 and the upper surface of the optical element 28. In one example, the first and second groups 68a and 68b of IC electrical pads 68 can be substantially equidistantly spaced from the first electrical pads 52 of the substrate 22 and the optical element electrical pads 72 with respect to the transverse direction T. Thus, the first and second groups 68a and 68b of IC electrical pads 68 can be substantially coplanar with each other along a respective plane that is defined by the longitudinal direction L and the lateral direction A. In one example, the first and second groups 68a and 68b of IC electrical pads 68 can be disposed within approximately 100 microns of being equally spaced from each of the first electrical pads 52 of the substrate 22 and the optical element electrical pads 72 with respect to the transverse direction T. For instance, the first and second groups 68a and 68b of IC electrical pads 68 can be disposed within approximately 50 microns of being equally spaced from each of the first electrical pads 52 of the substrate 22 and the optical element electrical pads 72 with respect to the transverse direction T. Further, the first and second groups 68a and 68b of IC electrical pads 68 can be equally spaced from each of the first electrical pads 52 of the substrate 22 and the optical element electrical pads 72 with respect to the transverse direction T.

As described above, the IC die 26 can be mounted to the pedestal 66 at the upper surface 62 of the IC heat spreader 34. By positioning the upper surface of the IC die 26 between the upper surface 40 of the substrate 22 and the upper surface of the optical element 28, the length of the electrical conductors 74a and 74b can be kept short. For instance, the length of the electrical conductors 74a and 74b can be kept substantially equal to each other. By shortening the length of the electrical conductors 74a and 74b, the electrical conductors 74a and 74b can carry high speed electrical signals while reducing or minimizing impedance discontinuities.

In one example, the first and second electrical conductors 74a and 74b can each have a length below 1 mm in one example. For instance, the length can be approximately 500 microns or less. In one example, the length can be in the range of approximately 50 microns to approximately 250 microns. It should be appreciated that the height of the IC heat spreader pedestal 66 may be adjusted with respect to the upper surface 40 of the substrate 22, so that the first group 68a of IC electrical pads 68 is offset with respect to the first electrical pads 52 of the substrate 22 a distance along the transverse direction T that is substantially equal to the offset of the second group 68b of the IC electrical pads 68 and the optical element electrical pads 72 along the transverse direction T. The wire bonds may be thought to form a stair step between the successive elements, minimizing the height difference each electrical conductor needs to bridge the respective gap.

The first group 68a of electrical pads can be aligned with respective ones of the first electrical pads 52 of the substrate 22 along a plane that is defined by the transverse direction T and the direction 73 substantially perpendicular to the select direction 45. The second group 68b of electrical pads can be aligned with respective ones of the optical element electrical pads 72 along the plane that is defined by the transverse direction T and the direction 73 substantially perpendicular to the select direction 45.

The lower surface of the IC die 26 may lie in substantially in the same plane as the upper surface 40 of the substrate 22. Alternatively, the lower surface of the IC die 26 can be offset with respect to the upper surface 40 of the substrate 22 along the transverse direction T. The upper surface of the IC die 26 can be offset from the upper surface 40 of the substrate 22 a distance along the transverse direction that is the sum of the thickness of the IC die 26 along the transverse direction T and the thickness of a bonding layer that bonds the IC die 26 to the upper surface 62 of the IC heat spreader 34. Thus, in one example, If the IC die 26 is approximately 200 microns thick and the bonding layer is approximately 25 microns thick, the upper surface of the IC die would be approximately 250 microns above the upper surface 40 of the substrate 22 along the transverse direction T.

Similarly, the upper surface of the optical element 28 can be offset from the upper surface 40 of the substrate 22 a distance along the transverse direction T that is the sum of the thickness of the optical element 28 along the transverse direction T, the thickness of the optical element heat spreader 36, and the thickness of a bonding layer that bonds the optical element to the upper surface 41 of the optical element heat spreader 36. Thus, as an example, if the optical element is 150 microns thick, the bonding layer is 25 microns thick, and the optical element heat spreader 36 is 250 microns thick, the upper surface of the optical element 28 would be 425 microns above the upper surface 40 of the substrate 22. This is even less of a displacement along the transverse direction T than between the IC die 26 and the proximal electrical pads 52 of the substrate 22.

Alternatively, it should be appreciated that the IC die 26 can lie in a plane that is angled with respect to a plane defined by the lateral direction A and the longitudinal direction L. For instance, as illustrated in FIG. 7B, the IC die 26 can be tilted such that the first edge 69 is offset with respect to the second edge 71 along the transverse direction T. In particular, the first edge 69 can be disposed below the second edge 71. As a result, the first group 68a of electrical pads 68 can be offset with respect to the second group 68b of electrical pads 68 along the transverse direction T. In particular, the first group 68a can be disposed below the second group 68b. The first group 68a of electrical pads 68 can be offset with respect to the first electrical pads 52 of the substrate 22 a distance along the transverse direction T that is less than the offset of the first group 68a of electrical pads 68 with respect to the first electrical pads 52 of the substrate 22 along the transverse direction T when the IC die 26 is oriented in the plane defined by the longitudinal direction L and the lateral direction A as described above with respect to FIG. 7A. In one example, the first group 68a of electrical pads 68 can be substantially coplanar with the first electrical pads 52 of the substrate 22. Similarly, the second group 68b of electrical pads 68 can be offset with respect to the optical element electrical pads 72 a distance along the transverse direction T that is less than the offset of the second group 68b of electrical pads 68 with respect to the optical element electrical pads 72 along the transverse direction T when the IC die 26 is oriented in the plane defined by the longitudinal direction L and the lateral direction A as described above with respect to FIG. 7A. In one example, the second group 68b of electrical pads 68 can be substantially coplanar with the electrical pads 52 of the optical element 28.

In one example, the upper surface of the IC heat spreader 34 at the pedestal 66 can be angled with respect to the plane defined by the longitudinal direction L and the lateral direction A. Thus, when the IC die 26 is mounted to the upper surface of the IC heat spreader 34 at the pedestal, the upper surface of the IC die 26 can be tilted in the manner described above with respect to FIG. 7B.

Alternatively, referring now to FIG. 7C, the lengths of the electrical conductors 74a and 74b can be further reduced by positioning the first and second groups pads 68a and 68b of IC electrical pads 68 substantially coplanar with the first electrical pads 52 of the substrate 22 and the optical element electrical pads 72. The coplanarity can be oriented along a plane that is defined by the longitudinal direction L and the lateral direction A. When the first and second groups 68a and 68b of IC electrical pads 68 are substantially coplanar with the first electrical pads 52 of the substrate 22 and the optical element electrical pads 72, the electrical conductors 74a and 74b do not span a vertical offset, and can thus be shortened with respect to the length of the electrical conductors 74a and 74b when the first and second groups 68a and 68b of IC electrical pads 68 are offset with respect to the first electrical pads 52 of the substrate 22 and the optical element electrical pads 72 along the transverse direction T. As illustrated in FIG. 7C, the upper surface 62 of the IC die 26 can be substantially coplanar with the optical element 28.

In one example, as described above with respect to FIG. 3B, the substrate 22 can be a composite substrate that includes first and second separate substrate bodies 38a and 38b that, in combination, define the respective entireties of both the opposed lateral edges 44 and the opposed longitudinal edges 46. The IC heat spreader 34 can be mounted to the first substrate body 38a and the optical element heat spreader 36 can be mounted to the second substrate body 38b. The second substrate body 38b can be offset with respect to the first substrate body 38a along the transverse direction. In particular, the second substrate body 38b can be offset below the first substrate body 38a. Thus, the upper surface 40 of the substrate 22 at the second substrate body 38b can be offset below the upper surface 40 of the substrate 22 at the first substrate body 38a. Similarly, the lower surface 42 of the substrate 22 at the second substrate body 38b can be offset below the lower surface 42 of the substrate 22 at the first substrate body 38a.

As a result, the optical element electrical pads 72 can be positioned substantially coplanar with the first electrical pads 52 of the substrate 22. Further, the electrical pads 72 can be aligned with respective ones of the first electrical pads 52 of the substrate 22 along a plane that includes the transverse direction T and the direction 73 substantially perpendicular to the select direction 45, both when the optical element electrical pads 72 is offset with respect to the electrical pads 52 of the substrate 22 along the transverse direction T, and when the optical element electrical pads 72 is substantially coplanar with the electrical pads 52 of the substrate 22.

Further, the height of the pedestal 66 of the IC heat spreader 34 can be selected such that the first group 68a of the IC electrical pads 68 are substantially coplanar with the first electrical pads 52 of the substrate 22 along a plane defined by the longitudinal direction L and the lateral direction A, and the second group 68b of the IC electrical pads 68 are substantially coplanar with the optical element electrical pads 72 along the plane defined by the longitudinal direction L and the lateral direction A. The first group 68a of electrical pads can further be aligned with respective ones of the first electrical pads 52 of the substrate 22 along a plane that is defined by the transverse direction T and the direction 73 substantially perpendicular to the select direction 45. The second group 68b of electrical pads can further be aligned with respective ones of the optical element electrical pads 72 along the plane that is defined by the transverse direction T and the direction 73 substantially perpendicular to the select direction 45.

In another example, the substrate 22 can be defined by a single monolithic body 38 as illustrated in FIG. 3A. As described above the height of the pedestal 66 of the IC heat spreader 34 can be selected such that the IC electrical pads 68 of the first group 68a are substantially coplanar with the first electrical pads 52 of the substrate 22 along a plane defined by the longitudinal direction L and the lateral direction A. Further, a recess can be formed into the upper surface 40 of the substrate body 38. The recess can have a depth along the transverse direction sufficient such that when the optical element heat spreader 36 is supported by the substrate 22 in the recess, the second group 68b of the IC electrical pads 68 are substantially coplanar with the optical element electrical pads 72 along the plane defined by the longitudinal direction L and the lateral direction A.

In another example, the substrate 22 can be defined by a single monolithic body 38 as illustrated in FIG. 3A. The height of the pedestal 66 of the IC heat spreader 34 can be selected such that the IC electrical pads 68 of the second group 68b are substantially coplanar with the optical element electrical pads 72 along a plane defined by the longitudinal direction L and the lateral direction A. Further, the first electrical pads 52 of the substrate 22 can have a height with respect to the upper surface 40 of the substrate 22 sufficient that they are substantially coplanar with the first group 68a of IC electrical pads 68.

Whether offset along the transverse direction T or substantially coplanar, it can be said that 1) the first group 68a of IC electrical pads 68 can be disposed adjacent the first electrical pads 52 of the substrate 22 along a plane that is defined by the longitudinal direction L and the lateral direction A, and 2) the second group 68b of IC electrical pads 68 can be disposed adjacent the optical element electrical pads 72 along the plane. For instance, the first group 68a of IC electrical pads 68 can be disposed adjacent the first electrical pads 52 of the substrate 22 along a direction 73 substantially perpendicular to the select direction 45. Similarly, the second group 68b of IC electrical pads 68 can be disposed adjacent the optical element electrical pads 72 along a direction 73 substantially perpendicular to the select direction 45.

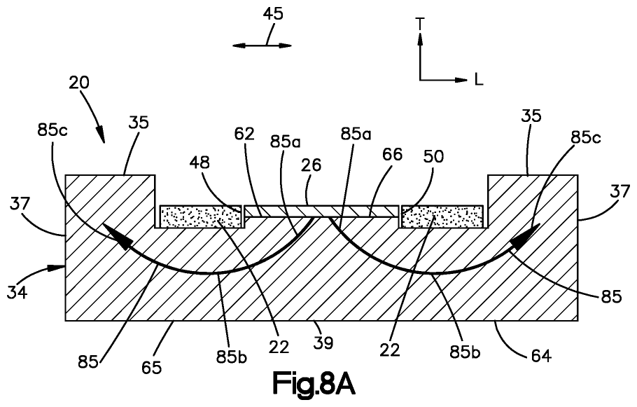

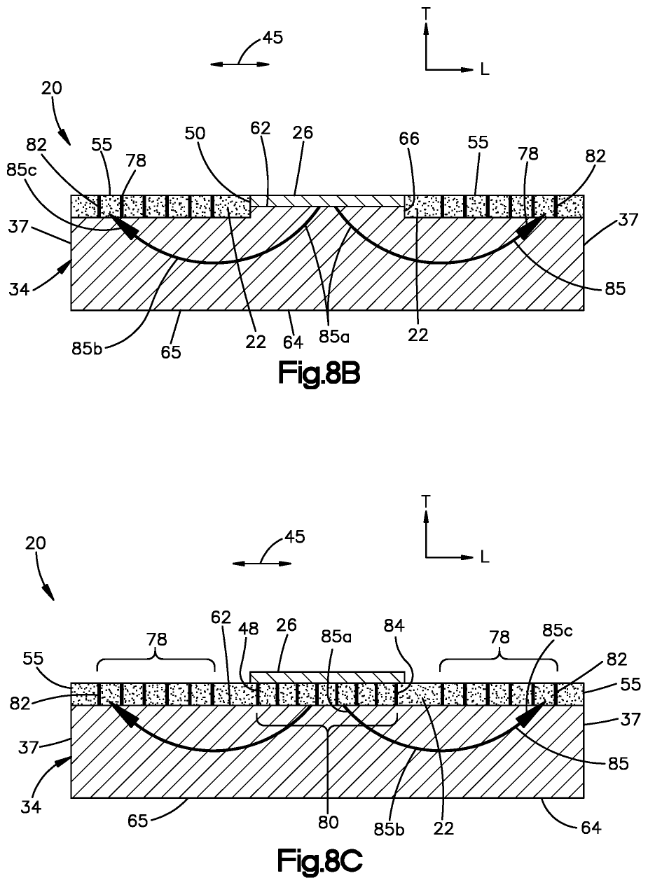

Referring now to FIG. 8A, during operation, at least a portion of the heat generated by the IC die 26 flows along a first heat dissipation path 85 so as to remove the generated heat from the optical element 28. The first heat dissipation path 85 can be defined by the IC heat spreader 34. Alternatively, as will be appreciated from the description below, the first heat dissipation path 85 can be defined by both the IC heat spreader 34 and the substrate 22. Thus, it can be said that the first heat dissipation path 85 can be at least partially defined by the IC heat spreader 34.

The first heat dissipation path 85 can include a first segment 85a that flows through the substrate 22 substantially along the transverse direction T. It can therefore be said that the first segment 85a crosses the substrate 22 along the transverse direction T. In particular, the first segment can extend down through the mounting region 48. Thus, when the mounting region 48 is defined by the mounting aperture 50, the first segment 85a can travel through the mounting aperture 50. In this regard, it should be appreciated that the first segment 85a can be oriented along the transverse direction T, or can extend along a direction having the transverse direction T as a directional component. For instance, the first segment 85a can flow down from the IC and into the IC heat spreader 34. When the IC heat spreader 34 includes the pedestal 66, the first segment 85a of the heat dissipation path 85 can flow through the pedestal and into the base 65. Further, the first segment 85a can be substantially linear, that is the heat flow can be mainly downward in a direction substantially parallel to the transverse direction T. Alternatively, the first segment 85a can define one or more curvatures.

The first heat dissipation path 85 can further include a second segment 85b that extends from the first segment 85a along a direction toward the end regions 37 of the IC heat spreader 34. Thus, the second segment 85b can extend along the substrate 22. The second segment 85b can further be disposed below the lower surface 42 of the substrate 22. It should therefore be appreciated that the second segment 85b can have a directional component that extends along one or both of the longitudinal direction L and the lateral direction A. Thus, the second segment 85b can extend away from the IC die 26 substantially along the select direction 45. It is recognized that the second segment 85b can also have a directional component along the transverse direction T. However, the directional component of the second segment 85b can be primarily along one or both of the longitudinal direction L and the lateral direction A. Further, the second segment 85b can be substantially linear, that is the heat flow can be mainly in a direction substantially parallel to the select direction 45. Alternatively, the second segment 85b can define one or more curvatures.

The first heat dissipation path 85 can further include a third segment 85c that extends from the second segment 85b substantially along the transverse direction T. In one example, the third segment 85c can extend up through the substrate 22. For instance, when the substrate 22 includes the heat transfer region 55 (see FIG. 3A), the third segment 85c can travel upward through the heat transfer region 55. In one example, the third segment 85c defined by the end regions 37 can be confined to a location that does not extend outside an outer footprint of the substrate 22 with respect to a respective plane that is defined by the lateral direction A and the longitudinal direction L (see FIGS. 1A-1B). As illustrated in FIGS. 1A-1B, an entirety of the IC heat spreader can be disposed below the substrate 22. Alternatively, when the heat transfer regions 55 are configured as notches 56, the third segment 85c can extend upward through the notches 56 (see FIG. 12B). Alternatively, the third segment 85c defined by the end regions 37 can extend to a location outside the footprint of the substrate 22 (see FIG. 1C).

Regardless, when the IC heat spreader 34 includes raised the raised regions 35 in one example, the third segment 85c can be said to cross the substrate 22 along the transverse direction T, as illustrated in FIG. 1C. In particular, the third segment 85c can extend upward from a first location below the lower surface 42 of the substrate 22. The third segment 85c can extend upward from the first location to a second location above the lower surface 42 of the substrate 22. For instance, the third segment 85c can extend upward from the first location to a second location above the upper surface 40 of the substrate 22. Whether the IC heat spreader 34 includes the raised regions 35 or not, the third segment 85c can extend upward from the second segment 85b.

Thus, the third segment 85c can be directed substantially opposite the first segment 85a. Further, the third segment 85c can be spaced from the first segment 85a along a direction perpendicular to the transverse direction T. For instance, the third segment 85c can be spaced from the mounting region 48 along the direction perpendicular to the transverse direction T. The direction perpendicular to the transverse direction T can be defined by the select direction 45. The third segment 85c can extend along the transverse direction T. It is recognized that the third segment 85c can also have a directional component along one or both of the longitudinal direction L and the lateral direction A. However, it can be said that the third segment 85c travels primarily along the transverse direction T. Further, the third segment 85c can be substantially linear that is the heat flow can be mainly upward in a direction substantially parallel to the transverse direction T. Alternatively, the third segment 85c can define one or more curvatures.

Referring now to FIG. 8B, the at least one heat transfer region 55 of the substrate 22 includes a respective at least one thermally conductive layer 78. The at least one thermally conductive layer 78 can place the upper surface 40 of the substrate 22 in thermal communication with the lower surface 42 of the substrate 22. Because the at least one thermally conductive layer 78 can be disposed peripherally with respect to the mounting region 48, the thermally conductive layer 78 can be referred to as a peripheral thermally conductive layer. In one example, the at least one thermally conductive layer 78 can define at least a portion of an outer edge of the substrate 22. For instance, the at least one thermally conductive layer 78 can define at least a portion of a respective one of the outer lateral edges 44. Thus, respective edges of the substrate 22 that are defined by thermally conductive layers 78 can be spaced from each other along the select direction. Alternatively, the at least one thermally conductive layer 78 can be enclosed by the substrate body 38 along a plane that is defined by the lateral direction A and the longitudinal direction L. The at least one thermally conductive layer 78 can be disposed outward from the mounting region 48. For instance, the at least one thermally conductive layer 78 can be disposed outward from the mounting region 48 along the select direction 45.

In one example, each of the heat transfer regions 55 can include a thermally conductive layer 78. Alternatively, one or both of the heat transfer regions 55 can include the thermally conductive layer 78, and the other one of the heat transfer regions 55 can define the notch 56 that receives a the IC heat spreader 34. In one example, the peripheral thermally conductive layer 78 can, for example, be defined by a high thermal conductivity metallic or ceramic slug, or can be defined by an array of thermally conductive peripheral pillars 82 that extend through the substrate body 38 from the upper surface 40 to the lower surface 42. The peripheral pillars 82 can be defined by metal (such as copper) plated and filled thru holes that extend through the substrate body 38 from the upper surface 40 to the lower surface 42. The layer 78 can be monolithic with the substrate body 38, or attached to the substrate body 38 as desired. In this example, it should be appreciated that at least a portion of the third segment 85c of the first heat dissipation path 85 can be defined by the thermally conductive layer 78 at the heat transfer region 55.

Additionally, referring to FIG. 8C, the substrate 22 can include a thermally conductive central layer 80 at the mounting region 48. The central thermally conductive layer 80 can place the upper surface 40 of the substrate 22 in thermal communication with the lower surface 42 of the substrate 22. In this regard, the mounting region 48 can also be referred to as a central heat transfer region. Thus, the pedestal 66 of the IC heat spreader 34 can be reduced in height or removed altogether such that the upper surface 62 of the IC heat spreader 34 is in mechanical contact, and thus thermal communication, with the central thermally conductive layer 80. The central thermally conductive layer 80 can, for example, be defined by a high thermal conductivity metallic or ceramic slug, or can be defined by an array of thermally conductive central pillars 84 that extend through the substrate body 38 from the upper surface 40 to the lower surface 42. The central pillars 84 can be defined by metal (such as copper) plated and filled thru holes that extend through the substrate body 38 from the upper surface 40 to the lower surface 42. The layer 80 can be monolithic with the substrate body 38, or attached to the substrate body 38 as desired. In one example, the peripheral thermally conductive layers 78 can be separate from the central thermally conductive layer 80 as described above. Alternatively, one or both of the peripheral thermally conductive layers 78 can be continuous with the central thermally conductive layer 80. For example, one or both of the peripheral thermally conductive layers 78 can be in contact with the central thermally conductive layer 80. Alternatively or additionally, one or both of the peripheral thermally conductive layers 78 can be monolithic with the central thermally conductive layer 80. In this example, it should be appreciated that at least a portion of the first segment 85a of the first heat dissipation path 85 can be defined by the thermally conductive layer 80 at the mounting region 48. It should be further appreciated in certain examples that the first heat dissipation path 85 can be a thermally conductive heat dissipation path along an entirety of its length.

The IC die 26 can be mounted to the upper surface of the central thermally conductive layer 80. Thus, heat dissipated by the IC die 26 can flow down through the central thermally conductive layer 80 to the IC heat spreader 34, and can flow through to the end regions 37 in the manner described above. The heat can then flow up through the peripheral thermally conductive layer 78.

It will be appreciated from the description above that the first heat dissipation path 85 for the IC die 26 extends through substrate 22 and wraps around at least a portion of the substrate 22.

By contrast, referring to 9A, the optical element heat spreader 36 is disposed above the upper surface 40 of the substrate 22. Thus, the optical element heat spreader 36 can at least partially or entirely define a second heat dissipation path 87 for the optical element 28. The second heat dissipation path 87 is disposed above the substrate 22. In one example, the second heat dissipation path 87 does not cross the substrate 22 along the transverse direction T. Further, in one example, the second heat dissipation path 87 does not wrap around the substrate 22. Rather, an entirety of the second heat dissipation path 87 defined by the optical element heat spreader 36 is maintained above the substrate 22. Thus, the substrate 22 can separate the second heat dissipation path 87 of the optical element 28 from at least a portion of the first heat dissipation path 85 of the IC die 26 with respect to the transverse direction T. At one or more locations where the first and second heat dissipation paths 85 and 87 are aligned along a plane that includes the longitudinal direction L and the lateral direction A, the first and second heat dissipation paths can be spaced from each other so as to maintain the first and second heat dissipation paths 85 and 87 in at least substantial thermal isolation from each other. It should be appreciated in certain examples that the second heat dissipation path 87 can be a thermally conductive heat dissipation path along an entirety of its length.

It should be appreciated that a method can be provided for dissipating heat from the optical transceiver. The method can include the step of generating heat at the electrical component 24 that is supported at the mounting region 48 of the substrate 22. The method can further include the step of dissipating at least a portion of the heat generated at the electrical component 24 through the electrical component heat spreader 34 that is in thermal communication with the electrical component 24 along the first heat dissipation path 85. As described above, the first heat dissipation path 85 can have the first segment 85a that extends from the electrical component 24 through the substrate 22, a second segment 85b that extends from the first segment 85a along the substrate 22 at a location below the substrate 22, and the third segment 85c that extends up from the second segment 85b so as to cross the substrate 22 at a location spaced from the first segment 85a. The method can further include the step of generating heat at the optical element 28 that is supported by the substrate 22 and is in electrical communication with the electrical component 24. The method can further include the step of dissipating at least a portion of the heat generated at the optical element 28 through the optical element heat spreader 36 that is in thermal communication with the optical element 28 and at least substantially thermally isolated from the IC heat spreader 34.

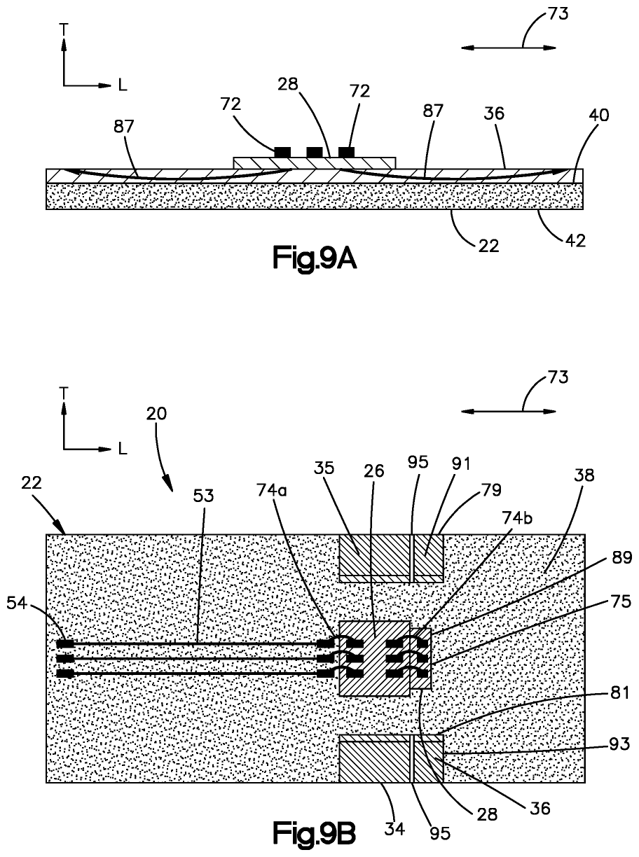

Alternatively, referring to FIG. 9B, it should be appreciated that the optical element heat spreader 36 can be configured as described above with respect to the IC heat spreader 34. Thus, the optical element heat spreader can include a pedestal that extends through an optical element mounting region 75 of the substrate 22. Thus, the optical element mounting region 75 can be configured as a mounting aperture 89 that extends through the substrate 22 along the transverse direction T as described above with respect to the mounting aperture 50. The mounting aperture 50 and the aperture of the optical element mounting region 75 can be spaced from each other. For instance, the mounting aperture 50 and the aperture of the optical element mounting region 75 can be spaced from each other along the longitudinal direction L. Alternatively, the optical element mounting region 75 can be configured as a respective central thermally conductive layer as described above with respect to the central thermally conductive layer 80. Thus, the central thermally conductive layer of the optical element mounting region 75 can be in thermal communication with the optical element heat spreader 36. The optical element heat spreader 36 can include a base that extends beneath the lower surface of the substrate 22 as described above with respect to the IC heat spreader 34.

The optical element heat spreader 36 can further include opposed end regions 79 that can be configured as described above with respect to the end regions 37 of the IC heat spreader 34. Thus, in one example, the optical element heat spreader 36 can include at least one raised region 91 that is constructed as described above with respect to the raised regions 35 of the IC heat spreader 34. In particular, the optical element heat spreader 36 can include a pair of end regions 79 that are spaced from each other and aligned with each other along the select direction 45. Further, the substrate 22 can include at least one heat transfer region 81 for the optical element heat spreader 36. The heat transfer region 81 can be constructed as described above with respect to the heat transfer region 55. Accordingly, the heat transfer region 81 can be configured as at least one opening that extends through the substrate 22 along the transverse direction T. The raised region 91 can extend at least into or through a respective one of the at least one opening. The opening can be configured as a notch 93 that is constructed as described above with respect to the notches 56. The notch 93, and thus the opening, can be configured to receive the raised region 91 of the optical element heat spreader 36. The raised region 91 can extend at least into or through the notch 93. The raised region 91 of the optical element heat spreader 36 can be spaced from the raised region 35 of the IC heat spreader 34 so as to define a gap 95 that maintains the IC heat spreader 34 and the optical element heat spreader 36 at least substantially thermally isolated from each other. Any suitable thermally insulative material can be disposed in the gap 95, such as air or any alternative material as desired.

Alternatively, the heat transfer region 81 can include at least one peripheral thermally conducive layer for the optical element heat spreader 36, such as a pair of peripheral thermally conducive layers. The peripheral thermally conducive layer for the optical element heat spreader 36 can be configured as described above with respect to the peripheral thermally conductive layer 78 of the IC heat spreader 34. Thus, the end regions 79 of the optical element heat spreader 36 can be placed in thermal communication with a lower surface of the thermally conductive layer for the optical element heat spreader 36 in the manner described above with respect to the end regions 37 and the thermally conductive layer 78. It should thus be appreciated that the second heat transfer path 87 can include first, second, and third segments as described above with respect to the first, second, and third segments 85a-85c of the first heat transfer path 85 (see FIG. 8A).

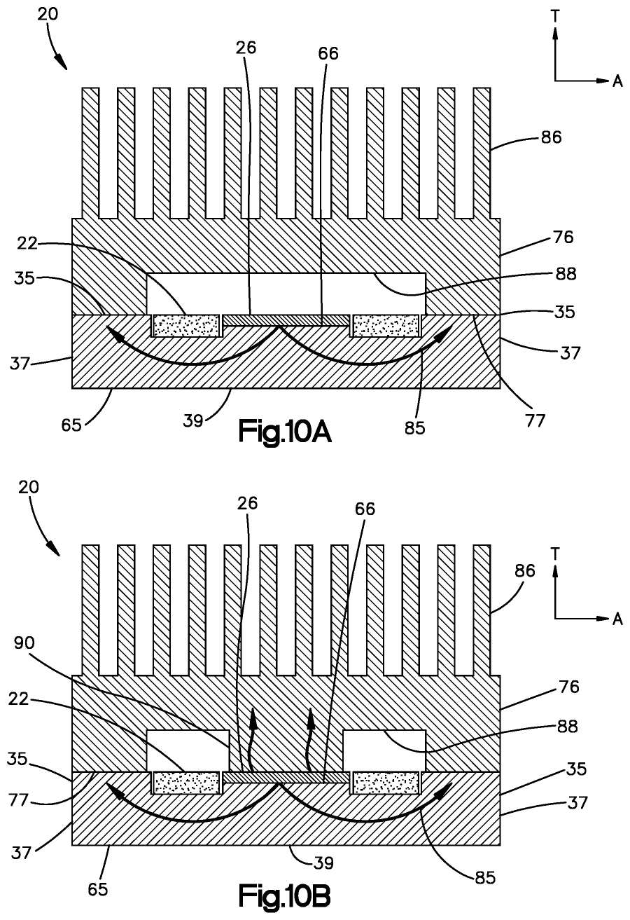

Referring now to FIG. 10A, the transceiver 20 can include a thermally conductive heat sink 76 that is in mechanical contact, and thus in thermal communication, with the upper surface 62 of the IC heat spreader 34. It should be appreciated that the term “thermal communication” as used herein should not be construed as limited to direct mechanical contact, unless otherwise indicated. For instance, the heat sink 76 can have a lower heat sink surface 77 that is in mechanical contact, and thus in thermal communication, with the upper surface 62 of the IC heat spreader 34 at the end regions 37. When the end regions 37 define the raised regions 35, the heat sink 76 can be in mechanical contact, and thus in thermal communication, with the upper surface 62 of the IC heat spreader 34 at the raised regions 35. Heat generated by the IC die 26 can thus flow thru the IC heat spreader 34 into the heat sink 76. The heat sink 76 can include a plurality of heat dissipation structures 86, such as fins or pins, to dissipate heat into the surrounding atmosphere. The heat sink 76 can further have a recessed region 88 that extends upward into the lower surface 77. The recessed region can be aligned with the IC die 26 along the transverse direction so as to provide clearance for the electrical conductors 74a and 74b (see FIG. 7A), the optical element 28, and optical couplings to and from the optical element 28.

It should also be appreciated that when the substrate 22 defines at least one peripheral thermally conductive layer 78, the heat sink 76 can be in mechanical contact, and thus thermal communication, with the upper surface of the at least one peripheral thermally conductive layer 78. Thus, heat dissipated by the IC die 26 can flow through the mounting region 48 and through the IC heat spreader 34.

Referring now to FIG. 10B, at least a portion of the heat dissipated by the IC die 26 can flow from the IC die 26 to the heat sink 76 without traveling through the IC heat spreader 34. In particular, the heat sink 76 can be further be in mechanical contact, and thus thermal communication, with a portion of the upper surface of the IC die 26. In particular, heat sink 76 can define a projection 90 that extends down along the transverse direction T and is in mechanical contact with the IC die 26. For instance, the projection 90 can contact at least a portion of the upper surface of the IC die 26. The projection 90 can contact the upper surface of the IC die 26 at locations spaced from the first and second groups 68a and 68b of the IC electrical pads 68. Thus, the heat sink 76 can define an auxiliary heat dissipation path from the IC die 26. In particular, the heat dissipation path can be defined directly from upper surface of the IC die 26, upward through the projection, and to a remainder of the heat sink 76 that is disposed above the IC die 26. A thermal adhesive or grease may be disposed between the heat sink 76 and IC heat spreader 34 (and if applicable further between the heat sink 76 and the IC die 26) to help provide a continuous conductive heat transfer path from the IC die 26 to the heat sink 76. The heat sink 76 can further be in mechanical contact, and thus thermal communication, with the optical element heat spreader 36 as desired.

Thus, an assembly can include the heat sink 76 that is configured to establish a thermally conductive path with a first component. For instance, the heat sink 76 can mechanically contact the first component. In one example, the heat sink 76 can directly contact the first component at the projection 90 in the manner described above. The first component can be an electrical component 24 as described above with respect to FIG. 1B. Thus, in one example, the electrical component 24 can be configured as an IC die 26. It should be appreciated, however, that the first component can be any suitable heat generating component. For instance, in another example, the first component can alternatively be configured as an optical component. For example the first component can be configured as a VCSEL.

The heat sink 76 can further define a gap between the lower surface of the heat sink 76 and a second component. The gap can be oriented along the transverse direction T. For instance, the upper end of the gap can be defined by the lower surface of the heat sink 76 at the recessed region 88. The lower end of the gap can be defined by the second component. Thus, in one example, the heat sink 76 does not contact the second component. Accordingly, the heat sink 76 can maintain conductive thermal isolation with respect to the second component, as the heat sink 76 does not contact the second component in such a manner so as to provide a thermal conductive path with the second component. Thus, the first and second components are thermally isolated from each other with respect to thermal conduction.

The second component can be in communication with the first component. That is, signals can be communicated from at least one of the first and second components to the other of the first and second components. In one example, the second component can be configured as an optical component 28 of the type described above. Thus, the optical component 28 can be configured as a VCSEL in one example. It should be appreciated, however, that the second component can be configured as any suitable component as desired. In other examples, for instance, it is envisioned that the second component can be configured as an electrical connector that is in electrical communication with the first component. In one example, the electrical connector can send electrical signals to the first component. Alternatively or additionally, the first component can send electrical signals to the second component. The electrical signals can be configured as electrical data. Alternatively, the electrical signals con be configured as electrical power. In examples whereby the first component is an integrated circuit, and the second component is an electrical connector, it is envisioned that the first and second components can be mounted onto a substrate, such that at least one electrical trace of the substrate can place the first and second components in communication with each other. In one example, the second component can include a plurality of electrical connectors that are each in communication with the first component. For instance, the electrical connectors can be arranged along a path that surrounds the second component. The heat sink 76 can be mechanically supported by the substrate or any suitable alternative structure as desired. In one example, the heat sink 76 can be mounted to the substrate.

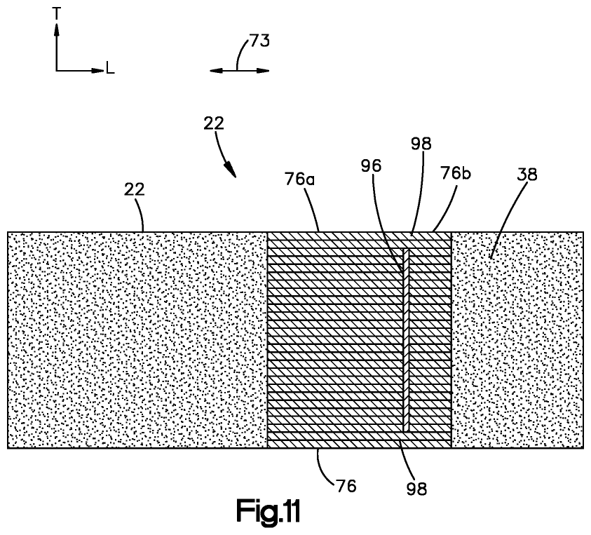

It should be appreciated, of course, that the heat sink 76 can be constructed so as to maintain substantial thermal isolation between the first component and the second component. Further, the heat sink 76 can be constructed so as to maintain substantial thermal isolation between the IC heat spreader 34 and the optical element heat spreader 36. In one example, referring now to FIG. 11, a first section 76a of the heat sink 76 can be in thermal communication with the IC die 26, and a second section 76b of the heat sink 76 can be in thermal communication with the optical element 28. For instance, the first section 76a can be in thermal communication with the IC heat spreader 34, and thus in thermal communication with the IC die 26. Alternatively or additionally, the first section 76a can be in mechanical contact with the IC die 26. Similarly, the second section 76b can be in thermal communication with the optical element heat spreader 36, and thus in thermal communication with the optical element 28. Alternatively or additionally, the second section 76b can be in mechanical contact with the optical element 28. Thus, at least 75 percent of the heat emitted from the IC die 26 can be dissipated out the heat sink 76. Similarly, at least 75 percent of heat emitted from the optical element 28 can be dissipated out the heat sink 76. The first section 76a can be monolithic with the second section 76b. Thus, a common heat sink 76 can define both the first section 76a and the second section 76b.

The common heat sink 76 can further maintain the substantial thermal isolation between the IC die 26 and the optical element 28. For instance, the common heat sink 76 can define a slot 96 that extends therethrough from the upper surface to the lower surface at a location between locations of the first and second sections 76a and 76b that are in thermal communication with the IC heat spreader 34 and the optical element heat spreader 36, respectively. The slot 96 can contain a thermal isolator, such as air or any suitable alternative material. For instance, a glass or polymer material, having low thermal conductivity, can be disposed in the slot 96. Thus, the slot 96 can define a region of thermal isolation between the IC heat spreader 34 and the optical element heat spreader 36, thereby allowing only minimal heat transfer from the IC die 26 to the optical element 28.

It should be appreciated that the common heat sink 76 can define margins 98 that extend between the first and second portions 76a and 76b. The margins 98 can be aligned with a central axis of elongation of the slot 96. However, the margins 98 can have a cumulative length along the central axis of elongation of the slot 96 that is less than the length of the slot 96 along the central axis of elongation. In one example, the cumulative distance can be less than 25% of the length of the slot 96 along the central axis of elongation. The common heat sink 76 can be referred to as a split heat sink because it is divided into the first and second sections 76a and 76b that have increased thermal resistance between them with respect to the thermal resistance of a remaining portion of the split heat sink 76. Alternatively, the first and second sections 76a and 76b can be separate from each other, and can define first and second heat sinks that are in thermal communication with the IC heat spreader 34 and the optical element heat spreader 36, respectively.

Thus, the IC heat spreader 34 can define a surface to which the IC die 26 is mounted, and the optical element heat spreader 36 can define a surface to which the optical element 28 is mounted. The surface can be substantially thermally isolated from each other such that the IC die 26 can operate at a higher temperature than the optical element 28 without causing the optical element 28 to increase in temperature to a level that substantially affects the performance or longevity of the optical element 28. It is recognized that the surface defined by the IC heat spreader 34 and the surface defined by the optical element heat spreader 36 can be surfaces of two separate heat spreaders that are positioned adjacent each other and spaced from each other as described above.

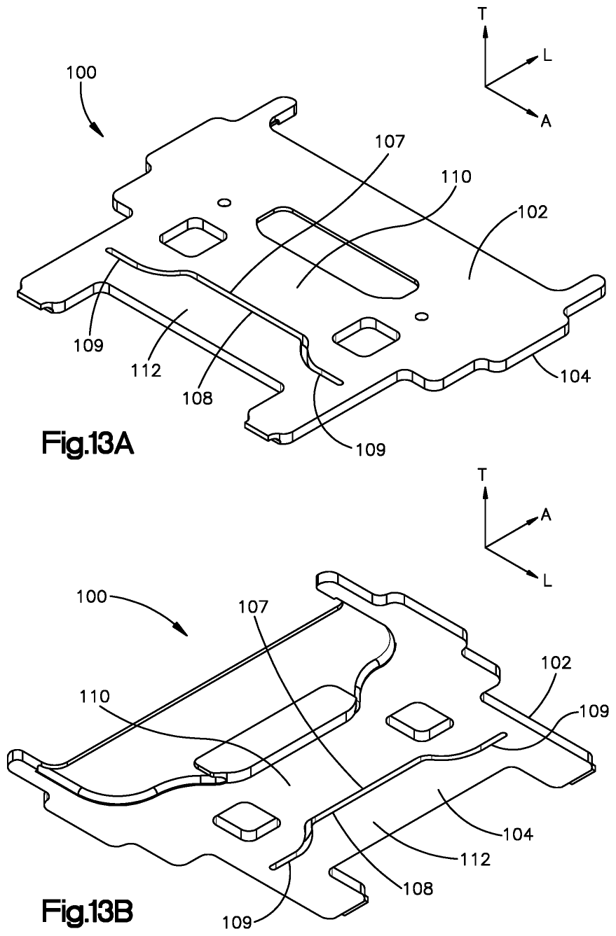

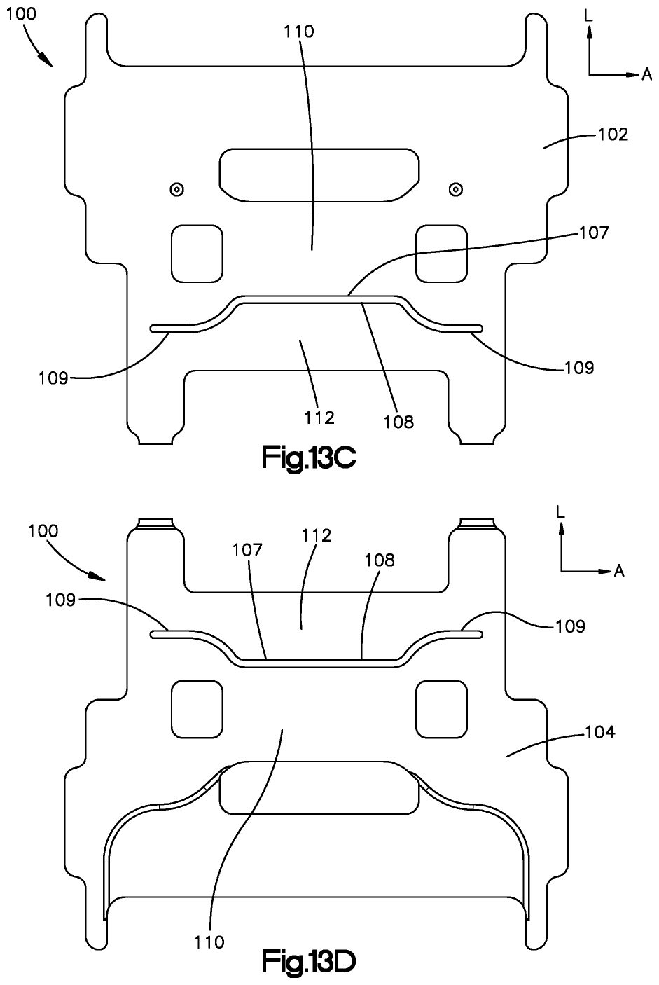

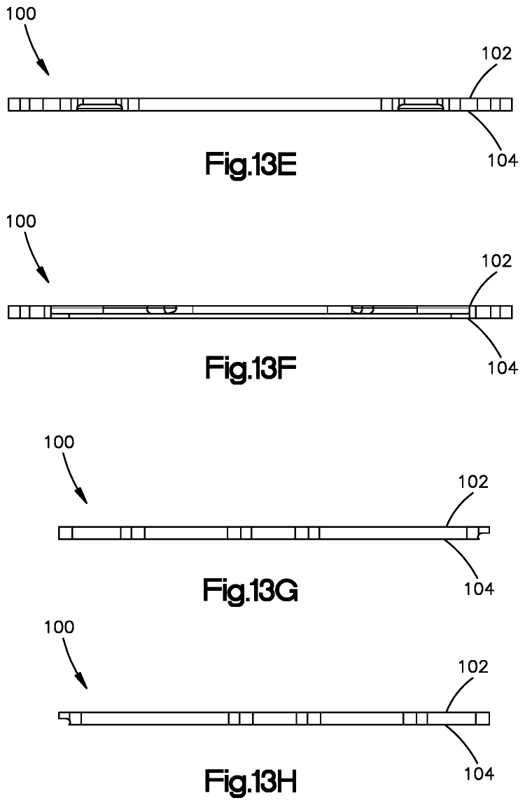

Referring now to FIGS. 12A-12F and 13A-13H in general, while the IC die 26 and the optical elements 28 can be supported by the substrate 22 in the manner described above, one or both of the IC die 26 and the optical elements 28 can be supported by the substrate 22 in accordance with another example. For instance, the IC die 26 and the optical elements 28 can be mounted to the thermal conductor 100. In particular, the IC die 26 and the optical elements 28 can be mounted to the upper surface 102 of the thermal conductor 100. The IC die 26 and the optical elements 28 can be offset with respect to each other along the direction 73 that is perpendicular to the select direction 45.

The thermal conductor 100 can further include a thermal isolation slot 108 that extends therethrough from the upper surface 102 to the lower surface 104. The thermal isolation slot 108 is disposed between the IC die 26 and the optical elements 28 along the direction 73 that is perpendicular to the select direction 45. Thus, the thermal isolation slot 108 can be disposed between the IC die 26 and the optical elements 28 along the longitudinal direction L. In one example, the thermal isolation slot 108 can be defined by an outer perimeter that is enclosed in its entirety by the thermal conductor 100. The outer perimeter can be defined by a plane that is defined by the longitudinal direction L and the lateral direction A. The thermal isolation slot 108 can extend along a distance in the lateral direction A, so as to span a majority of the width of the thermal conductor 100 along the lateral direction A. For instance, the thermal isolation slot 108 can span at least 80% of the width of the thermal conductor 100 along the lateral direction A. In one example, the thermal isolation slot 108 can span at least 90% of the width of the thermal conductor 100 along the lateral direction A. For example, the thermal isolation slot 108 can span at least 95% of the width of the thermal conductor 100 along the lateral direction A.

Because the thermal isolation slot 108 is disposed between the IC die 26 and the optical elements 28, the thermal isolation slot is configured to disrupt a linear thermal conductive path from the IC die 26 to the optical elements 28 along the thermal conductor 100. Thus, no straight line exists from the IC die 26 of any of the optical elements 28 without crossing the thermal isolation slot 108 in one example. Thus, the thermal isolation slot 108 can at least substantially thermally isolate the IC die 26 from the optical elements 28 with respect to thermal conductivity along the thermal conductor 100. The thermal isolation slot 108 can define an air gap, or can alternatively be defined by any suitable thermally isolative material.

The thermal isolation slot 108 can define an intermediate region 107 and respective first and second terminal ends 109 that extend out from opposed ends of the intermediate region 107. The ends 109 can be opposite each other along the select direction 45, or the lateral direction A. Thus, it should be appreciated that the thermal isolation slot 108 can be elongate along the select direction 45. The intermediate region 107 can extend between the IC die 26 and the optical elements 28. Further, the intermediate region 107 can be aligned with one or both of the IC die 26 and the optical elements 28. In this regard, it is recognized that the IC die 26 and the optical elements 28 can have different lengths along the select direction 45, or lateral direction A. Thus, a first portion of the intermediate region 107 can be aligned with each of the IC die 26 and the optical elements 28 along the longitudinal direction L.

Further, a second portion of the intermediate region 107 can extend outboard with respect to one of the IC die 26 and the optical elements 28 with respect to the lateral direction A, and can be aligned with the other of the IC die 26 and the optical elements 28 along the longitudinal direction L. Thus, each of the IC die 26 and the optical elements 28 can be disposed entirely between the ends 109 with respect to the select direction 45. At least a portion of the ends 109 of the slot 108 can extend along the longitudinal direction L from the intermediate region 107 in a direction away from the IC die 26. Accordingly, at least a portion of the ends 109 can be aligned with the optical elements 28 along the select direction 45. Thus, at least a portion of the ends 109 can be aligned with the optical elements 28 along longitudinal direction A. Accordingly, the intermediate region 107 and the ends 109 can combine so as to at least partially surround three sides of the optical elements 28. In one example, the ends 109 can present a convex surface that faces the optical elements 28 and is spaced from the optical elements along the lateral direction A. For instance, the ends 109 can be curved or otherwise geometrically configured as they flare away from opposed ends of the intermediate region 107.

The thermal conductor 100 can define a first region 110 and a second region 112 that is separated from the first region 110 along the longitudinal direction L by the thermal isolation slot 108. Otherwise stated, the first and second regions 110 and 112 are disposed on opposite sides of the slot 108 with respect to the longitudinal direction L. The IC die 26 can be mounted to the upper surface 102 at the first region 110, and the optical elements 28 can be mounted to the upper surface 102 at the second region 112. During operation, the thermal conductor 100 can dissipate heat from the optical elements 28. Thus, even though the IC die 26 is mounted to the thermal conductor 100, the thermal conductor can be referred to as an optical element heat spreader. For instance, the second region 112 of the thermal conductor can define the optical element heat spreader.

The thermal isolation slot 108 can define a width that is suitable to thermally isolate the IC die 26 from the optical elements 28. The width can be perpendicular to the thickness of the thermal conductor 100, and further perpendicular to the length of the thermal isolation slot 108 at the location that the width is measured. When the thermal conductor 100 is planar along a plane defined by the lateral direction A and the longitudinal direction L, the thickness is oriented along the transverse direction T. In one example, the width can be in a range having a lower end of approximately 25 microns, and an upper end of 500 microns, for instance in low data transfer speed applications. In high data speed applications, the lower end of the range can be approximately 25 microns, and the upper end of the range can be approximately 200 microns. For instance, the lower end of the range can be approximately 50 microns, and the upper end of the range can be approximately 150 microns. It should be appreciated in one example that the width of the slot 108 can be constant from the upper surface 102 to the lower surface 104. In another example, the slot 108 can flare outward as it extends downward between the upper surface 102 and the lower surface 104. For instance the slot 108 can flare outward from the upper surface 102 to the lower surface 104. In one example, the slot 108 can flare straight and linearly outward. Alternatively, at least a portion of the slot 108 can flare curvilinearly outward. Alternatively still, the slot 108 can flare outwardly along one or more straight and linear segments. Thus, the width of the slot 108 at the upper surface 102 can be less than the width of the slot at the lower surface 104.

The thickness of the thermal conductor 100 can be in a range having a lower end of approximately 150 microns and an upper end of approximately 300 microns. For instance, the thickness of the thermal conductor 100 can be approximately 150 microns. The thickness can be measured at the slot or any location between the IC die 26 and the optical elements 28. The thickness can be constant along the thermal conductor 100 at regions that are coplanar along the lateral direction A and the longitudinal direction L. Thus, when an entirety of the thermal conductor 100 is planar, the thickness of the thermal conductor 100 can be constant along the entirety of the thermal conductor 100.

The IC heat spreader 34 can be constructed in the manner described above. For instance, the base 65 of the IC heat spreader 34 can extend along the lower surface 42 of the substrate 22 as described above. Thus, the base 65 of the IC heat spreader 34 can be spaced from the thermal conductor 100 along the transverse direction T. The raised regions 35 can extend at least into notches 56 of the substrate 22 along the transverse direction T. Thus, the upper surface 62 of the IC heat spreader 34 at the raised end regions 37 can be disposed above the lower surface 42 of the substrate 22 with respect to the transverse direction T. In one example, the upper surface 62 of the IC heat spreader 34 at the raised end regions 37 can be disposed between above the lower surface 42 of the substrate 22 and the upper surface 40 with respect to the transverse direction T. In another example, the raised end regions 37 can extend above the substrate 22. Thus, the upper surface 40 of the substrate 22 can be disposed between the lower surface 42 of the substrate 22 and the upper surface 62 of the IC heat spreader 34 at the raised end regions 37 with respect to the transverse direction T. The raised end regions 37 can be spaced from the thermal conductor 100. Alternatively, the raised end regions 37 can contact the thermal conductor 100 as desired. Further, in one example, the end regions 37 can be confined within a footprint of the substrate 22 along a plane that is defined by the lateral direction A and the longitudinal direction L. Thus, in one example, the raised end regions 37 do not extend out with respect to the footprint of the substrate 22.

Further, the pedestal 66 can extend from the base 65 at least into the mounting aperture 50 of the substrate 22 along the transverse direction T. For instance, in one example, the pedestal 66 can extend from the base 65 through the mounting aperture 50. The upper surface 62 of the IC heat spreader 34 at the pedestal 66 can contact the lower surface 104 of the thermal conductor 100. Thus, the IC heat spreader 34 can be placed in conductive thermal communication with the thermal conductor 100. In this regard, it should be appreciated that the thermal conductor 100 can extend over at least a portion of the mounting aperture 50 of the substrate 22. For instance, the thermal conductor 100 can extend over an entirety of the mounting aperture 50. In one example, at least a portion of the upper surface 62 of the IC heat spreader 34 at the pedestal 66 can be in surface contact with the lower surface 104 of the thermal conductor 100. For example, an entirety of the upper surface 62 of the IC heat spreader 34 at the pedestal 66 can be in surface contact with the lower surface 104 of the thermal conductor 100.

Further, at least a portion of the pedestal 66 can be aligned with at least a portion of the IC die 26 that is mounted to the upper surface 102 along the transverse direction T. In one example, the pedestal 66 can be aligned with the IC die 26 along the transverse direction T. Thus, the IC die 26 is placed in thermal conduction with the IC heat spreader 34 through the thermal conductor 100. In particular, heat can conductively dissipate from the IC die 26 by flowing through the thermal conductor 100 along the transverse direction T to the pedestal 66. The IC heat spreader 34 can conduct and dissipate the heat from the pedestal 66 in the manner described above with respect to 8A-8C. The thermal isolation slot 108 substantially thermally isolates the optical elements 28 from the IC heat spreader 34.

As described above, the first end of the at least one first electrical conductor 74a can be electrically connected to a respective one of the at least one first electrical pad 52 of the substrate 22, and the second end of the at least one first electrical conductor 74a can be electrically connected to a respective one of the first group 68a of at least one IC electrical pad 68. For instance, the transceiver 20 can include a plurality of first electrical conductors 74a that are electrically connected at a first end to a respective one of the plurality of first electrical pads 52 of the substrate 22, and at a second end to a respective one of the first group 68a of the plurality of IC electrical pads 68. Further, as described above, the first end of the at least one second electrical conductor 74b can be electrically connected to a respective one of the second group 68b of at least one IC electrical pad 68, and the second of the at least one second electrical conductor 74b can be electrically connected to the at least one optical element electrical pad 72. For instance, the transceiver 20 can include a plurality of second electrical conductors 74b that are electrically connected at a respective first end to a respective one of the second group 68b of the plurality of IC electrical pads 68, and at a second end to a respective one of the plurality of optical element electrical pads 72. In one example, the electrical conductors 74a and 74b can be defined by one or more of electrically conductive wires or ribbons that are bonded to pads using well known wire and/or ribbon bonding techniques.

As illustrated in FIG. 12C, the IC die 26 can have a height that is greater than the optical elements 28. Thus, the upper surface of the optical elements 28 can be disposed between the upper surface of the IC die 26 and the upper surface of the substrate 22 with respect to the transverse direction T. Thus, the length of the at least one first electrical conductor 74a can be greater than the length of the at least one second electrical conductor 74b. The upper surface 102 at the first region 110 can be substantially coplanar with the upper surface 102 at the second region 112.

Referring now to FIG. 12D, in one example, the at least one IC electrical pad 68 of the second group 68b can be at least substantially coplanar with the at least one optical element electrical pads 72. For instance, upper surface 102 of the thermal conductor 100 at the second region 112 can have a height along the transverse direction T that is greater than the height of the upper surface 102 of the thermal conductor at the first region 110. In one example, the second region 112 of the thermal conductor can define a thickness along the transverse direction T from the upper surface 102 to the lower surface 104 that is greater than that of the first region 110. Accordingly, when the optical elements 28 are mounted to the upper surface 102 at the second region 112, the at least one IC electrical pad 68 of the second group 68b can be at least substantially coplanar with the at least one optical element electrical pads 72.

As illustrated in FIG. 12E, the first electrical pads 52 of the substrate 22 can be offset with respect to the first group 68a of IC electrical pads 68 along the transverse direction T, and the second group 68b of IC electrical pads 68 can be offset with respect to the optical element electrical pads 72 along the transverse direction T. For instance, the first and second groups 68a and 68b of electrical pads of the IC die 26 can be disposed between the first electrical pads 52 of the substrate 22 and the optical element electrical pads 72 along the transverse direction T. For instance, at least a recessed portion 114 of the upper surface 102 of the first region 110 of the thermal conductor 100 can be recessed with respect to the upper surface 102 of the second region 112 of the thermal conductor 100 along the transverse direction T. Further, a portion 114 of the upper surface 102 of the first region 110 can be recessed with respect to at least one other portion of the upper surface 102 of the first region 110. The portion 114 can extend into the mounting aperture 50 of the substrate 22. Thus, the upper surface 102 of the portion 114 can be recessed with respect to the upper surface 40 of the substrate 22.

The IC die 26 can be mounted to the upper surface 102 at the recessed portion 114. In one example, the upper surface 102 at the recessed portion 114 can be recessed with respect to the upper surface 102 at the second region 112 a distance along the transverse direction such that the first electrical pads 52 of the substrate 22 are offset with respect to the first group 68a of IC electrical pads 68 along the transverse direction T, and the second group 68b of IC electrical pads 68 can be offset with respect to the optical element electrical pads 72 along the transverse direction T. For example, the first and second groups 68a and 68b of IC electrical pads 68 can be substantially equidistantly spaced from the first electrical pads 52 of the substrate 22 and the optical element electrical pads 72 with respect to the transverse direction T. Thus, the first and second groups 68a and 68b of IC electrical pads 68 can be substantially coplanar with each other along a respective plane that is defined by the longitudinal direction L and the lateral direction A. Alternatively, the upper surface 102 at the recessed portion 114 can be recessed with respect to the upper surface 102 at the second region 112 a distance along the transverse direction T such that the IC electrical pads 68 of the second group 68b of IC electrical pads 68 are substantially coplanar with the optical element electrical pads 72.

Alternatively still, referring to FIG. 12F, the first group 68a of IC electrical pads can be at least substantially coplanar with the electrical pads 52 of the substrate 22. Further, the second group 68b of IC electrical pads can be at least substantially coplanar with the optical element electrical pads 72. For instance, the IC die 26 can be tilted such that the first edge 69 is offset with respect to the second edge 71 along the transverse direction T. In particular, the first edge 69 can be disposed below the second edge 71. As a result, the first group 68a of electrical pads 68 can be offset with respect to the second group 68b of electrical pads 68 along the transverse direction T. In particular, the first group 68a can be disposed below the second group 68b. The first group 68a of electrical pads 68 can be offset with respect to the first electrical pads 52 of the substrate 22 a distance along the transverse direction T that is less than the offset of the first group 68a of electrical pads 68 with respect to the first electrical pads 52 of the substrate 22 along the transverse direction T when the IC die 26 is oriented in the plane defined by the longitudinal direction L and the lateral direction A as described above with respect to FIG. 7A. In one example, the first group 68a of electrical pads 68 can be substantially coplanar with the first electrical pads 52 of the substrate 22. Similarly, the second group 68b of electrical pads 68 can be offset with respect to the optical element electrical pads 72 a distance along the transverse direction T that is less than the offset of the second group 68b of electrical pads 68 with respect to the optical element electrical pads 72 along the transverse direction T when the IC die 26 is oriented in the plane defined by the longitudinal direction L and the lateral direction A as described above with respect to FIG. 7A. In one example, the second group 68b of electrical pads 68 can be substantially coplanar with the electrical pads 52 of the optical element 28.

In one example, at least an angled portion 116 of the upper surface 102 of the first region 110 of the thermal conductor 100 can be angled with respect to a plane defined by the longitudinal direction L and the lateral direction A. Thus, the angled portion 116 can be angled with respect to the upper surface 102 of the second region 112 of the thermal conductor 100 along the transverse direction T. Further, the angled portion 116 of the upper surface 102 of the first region 110 can be recessed with respect to at least one other portion of the upper surface 102 of the first region 110. The angled portion 116 can extend into the mounting aperture 50 of the substrate 22. Thus, when the IC die 26 is mounted to the upper surface 102 of the thermal conductor 100 at the angled portion 116 of the thermal conductor 100, the upper surface of the IC die 26 can be tilted in the manner described above. It should be appreciated that the upper surface 62 of the IC heat spreader 34 at the pedestal 66 can likewise be angled so as to remain in surface contact with the lower surface 104 of the thermal conductor 100 at the angled portion 116.

Further, as described above with respect to FIGS. 10A-10B, the thermally conductive heat sink 76 can be placed in mechanical contact, and thus in thermal communication, with at least one or both of the IC heat spreader 34 and the IC die 26. Thus, the heat sink 76 can be in mechanical contact with the raised end regions 37. The heat sink 76 can further define the recessed region 88 that is aligned with the IC die 26, and the first and second electrical conductors 74a and 74b are aligned with the recessed region 88. Further, the heat sink 76 can define the projection 90 that contacts the IC die 26 at a location spaced from the first and second electrical conductors 74a and 74b. As illustrated in FIG. 11, the heat sink 76 can define the first section 76a that is in thermal communication with the IC die 26, and the second section 76b that is in thermal communication with the optical elements 28. Further, the heat sink 76 can define the slot 96 disposed between the first and second sections 76a and 76b so as to place the IC die 26 and the optical elements 28 in substantially thermal isolation from each other.

It should be appreciated that the illustrations and discussions of the embodiments shown in the figures are for exemplary purposes only, and should not be construed limiting the disclosure. For example, the preceding description has generally been applicable to a mid-board mounted optical transceiver; however, the invention is not so limited. It may be used in a front panel mounted optical transceiver. In this case the electrical element heat spreader and the optical element heat spreader may be in thermal communication with a transceiver housing, rather than a heat sink. When the transceiver is inserted in a front panel the transceiver housing is in thermal communication with a heat sink external to the transceiver. One skilled in the art will appreciate that the present disclosure contemplates various embodiments. Additionally, it should be understood that the concepts described above with the above-described embodiments may be employed alone or in combination with any of the other embodiments described above. It should be further appreciated that the various alternative embodiments described above with respect to one illustrated embodiment can apply to all embodiments as described herein, unless otherwise indicated.

1. An optical transceiver comprising:
a substrate defining an upper surface and a lower surface opposite each other along a transverse direction, and at least one first electrical pad disposed on the upper surface;
an IC heat spreader, and IC die in thermal communication with the IC heat spreader;
a first group of at least one IC electrical pad disposed on the IC die;
a second group of at least one IC electrical pad disposed on the IC die;
an thermal conductor, and an optical element in thermal communication with the thermal conductor;
at least one optical element electrical pad disposed on the optical element,
at least one first electrical conductor that extends from a respective one of the at least one first electrical pad of the substrate to a respective one of the at least one IC electrical pad of the first group, and
at least one second electrical conductor that extends from a respective one of the at least one IC electrical pad of the second group to a respective one of the at least one optical element electrical pad.

2-3. (canceled)

4. The optical transceiver as recited in claim 1, wherein the IC die is mounted to the IC heat spreader.

5. The optical transceiver as recited in claim 1, wherein the optical element is mounted to the thermal conductor.

6. The optical transceiver as recited in claim 1, wherein the first and second groups of at least one IC electrical pad are disposed between the at least one first electrical pad of the substrate and the at least one optical element electrical pad with respect to the transverse direction.

7. (canceled)

8. The optical transceiver as recited in claim 6, wherein the first group of at least one IC pad is at least substantially coplanar with the second group of at least one IC pad.

9. The optical transceiver as recited in claim 1, wherein the first group of at least one IC pad is at least substantially coplanar with the proximal at least one electrical pad, and the second group of at least one IC pad is at least substantially coplanar with the at least one optical element electrical pad.

10-12. (canceled)

13. The optical transceiver as recited in claim 9, wherein the upper surface extends along a plane defined by a longitudinal direction and a lateral direction, the longitudinal direction is substantially perpendicular to the transverse direction, and the lateral direction is substantially perpendicular to each of the longitudinal direction and the transverse direction, and the IC die is tilted with respect to the plane.

14. (canceled)

15. The optical transceiver as recited in claim 1, wherein the substrate comprises first and second separate substrate bodies, the IC heat spreader is supported by the first substrate body, and the thermal conductor is supported by the second substrate body.

16-18. (canceled)

19. The optical transceiver as recited in claim 1, wherein the substrate defines a mounting region configured to support the IC die.

20. The optical transceiver as recited in claim 19, wherein the mounting region comprises a mounting aperture that extends through the substrate from the upper surface to the lower surface.

21. The optical transceiver as recited in claim 20, wherein the IC heat spreader comprises a base that extends along the lower surface of the substrate, the IC heat spreader comprises a pedestal that extends up from the base, and at least one of the pedestal and the IC die extends at least into the mounting aperture.

22-32. (canceled)

33. The optical transceiver as recited in claim 1, wherein the substrate defines edges that are opposite each other along a select direction, and the IC heat spreader defines end regions that are opposite each other along the select direction.

34. The optical transceiver as recited in claim 33, wherein the substrate defines at least one heat transfer region offset from the IC die along the select direction

35. The optical transceiver as recited in claim 34, wherein the heat transfer region comprises a notch that extends into one of the edges of the substrate.

36. (canceled)

37. The optical transceiver as recited in claim 36, wherein the IC heat spreader defines respective end regions having raised regions that extend into respective ones of the notches.

38. (canceled)

39. The optical transceiver as recited in claim 37, wherein the raised end regions do not extend out with respect to a footprint of the substrate.

40. The optical transceiver as recited in claim 39, further comprising a heat sink that is in mechanical contact with the raised regions, the heat sink defining a recessed region aligned with the IC die, wherein the first and second electrical conductors are aligned with the recessed region.

41. (canceled)

42. The optical transceiver as recited in claim 40, wherein the heat sink comprises a first section in thermal communication with the IC die.

43. The optical transceiver as recited in claim 42, wherein the heat sink comprises a second section in thermal communication with the optical element.

44. The optical transceiver as recited in claim 43, wherein the heat sink defines a slot disposed between the first and second sections so as to place the IC die and the optical element in substantially thermal isolation from each other.

45-165. (canceled)
